(19) United States
(12) Patent Application Publication
(10) Pub. No.: US 2026/0026194 A1
(43) Pub. Date: Jan. 22, 2026

(54) Array Substrate, Display Panel and Display Apparatus

(71) Applicant: BOE TECHNOLOGY GROUP CO., LTD., Chaoyang District, Beijing (CN)

(72) Inventors: Dongni Liu, Beijing (CN); Minghua Xuan, Beijing (CN); Xue Dong, Beijing (CN); Zhenyu Zhang, Beijing (CN); Shunhang Zhang, Beijing (CN); Zhen Zhang, Beijing (CN); Peirou Li, Beijing (CN); Yunsik Im, Beijing (CN); Lianfu Yu, Beijing (CN)

(21) Appl. No.: 18/852,824

(22) PCT Filed: Dec. 13, 2023
(86) PCT No.: PCT/CN2023/138571

§ 371 Date: Sep. 30, 2024

(51) Int. Cl. H10K 59/121; H10D 86/40; H10D 86/60; H10K 59/131; H10K 59/80

(52) U.S. Cl. CPC H10K 59/1213; H10D 86/443; H10D 86/60; H10K 59/131; H10K 59/8792

(57) ABSTRACT

An array substrate includes a plurality of pixel driving circuits arranged in rows and columns, and each of the plurality of pixel driving circuits includes a plurality of transistors, and the plurality of transistors includes at least a writing transistor. The array substrate includes a base substrate, a first source-drain metal layer disposed on a side of the base substrate, a transistor distribution layer disposed on a side of the first source-drain metal layer away from the base substrate, and a second source-drain metal layer disposed on a side of the transistor distribution layer away from the base substrate. The first source-drain metal layer includes data signal lines. The transistor distribution layer is provided with an active layer pattern of the writing transistor, and the active layer pattern of the writing transistor is electrically connected to a data signal line. The second source-drain metal layer includes anode transfer patterns.

### CROSS-REFERENCE TO RELATED APPLICATION

This application is the United States national phase of International Patent Application No. PCT/CN2023/138571 filed Dec. 13, 2023, the disclosure of which is hereby incorporated by reference in its entirety.

### BACKGROUND OF THE INVENTION

### Field of the Invention

The present disclosure relates to the field of display technologies, and in particular, to an array substrate, a display panel and a display apparatus.

### Description of Related Art

At present, display screens with a large size and ultra-high definition are favored by more and more users. From 720P to 1080P, and from 2K to 4K and then to 8K, the display screen resolution is constantly upgraded. PPI (pixels per inch) is the unit of image resolution, which represents the number of pixels per inch. Therefore, the higher the PPI value is, the higher the density in which the display screen can display images. The higher the display density, the higher the realistic degree. Thus, high definition or ultra-high definition display is achieved.

### SUMMARY OF THE INVENTION

In an aspect, an array substrate is provided, which includes a plurality of pixel driving circuits arranged in rows and columns. Each of the plurality of pixel driving circuits includes a plurality of transistors, and the plurality of transistors includes at least a writing transistor.

The array substrate includes a base substrate, a first source-drain metal layer disposed on a side of the base substrate, a transistor distribution layer disposed on a side of the first source-drain metal layer away from the base substrate, and a second source-drain metal layer disposed on a side of the transistor distribution layer away from the base substrate. The first source-drain metal layer includes data signal lines. The transistor distribution layer is provided with an active layer pattern of the writing transistor, and the active layer pattern of the writing transistor is electrically connected to a data signal line of the data signal lines. The second source-drain metal layer includes anode transfer patterns.

In some embodiments, the transistor distribution layer includes at least two transistor distribution sub-layers that are stacked, and each of the at least two transistor distribution sub-layers includes an active film layer and a gate film layer that are stacked. The active film layer includes an active layer pattern of a transistor of the plurality of transistors, and the gate film layer includes a gate pattern of the transistor. The writing transistor is located in one of the at least two transistor distribution sub-layers.

The active layer pattern of the writing transistor is electrically connected to the data signal line through a drain transfer pattern of the writing transistor, and the drain transfer pattern of the writing transistor is located in a first transfer gate film layer. The first transfer gate film layer is located in the at least two transistor distribution sub-layers and/or between two adjacent transistor distribution sub-layers.

In some embodiments, the active layer pattern of the writing transistor is connected to a source transfer pattern of the writing transistor. The source transfer pattern of the writing transistor is located in a second transfer gate film layer, and the second transfer gate film layer is located in the at least two transistor distribution sub-layers and/or between two adjacent transistor distribution sub-layers.

In some embodiments, the pixel driving circuit further includes a driving transistor and a sensing transistor. An active layer pattern of the driving transistor is electrically connected to an anode transfer pattern of the anode transfer patterns, and an active layer pattern of the sensing transistor is electrically connected to the anode transfer pattern.

The active layer pattern of the driving transistor is connected to the anode transfer pattern through a source transfer pattern of the driving transistor, the source transfer pattern of the driving transistor is located in a third transfer gate film layer, and the third transfer gate film layer is located in the at least two transistor distribution sub-layers and/or between two adjacent transistor distribution sub-layers.

In some embodiments, the transistor distribution layer includes a first transistor distribution sub-layer and a second transistor distribution sub-layer that are stacked, and the first transistor distribution sub-layer is closer to the base substrate than the second transistor distribution sub-layer.

The transistor distribution layer further includes a fourth gate film layer located between the first transistor distribution sub-layer and the second transistor distribution sub-layer. The writing transistor is located in the first transistor distribution sub-layer. The drain transfer pattern and a source transfer pattern of the writing transistor are located in the fourth gate film layer, and the source transfer pattern of the writing transistor is connected to the active layer pattern of the writing transistor.

In some embodiments, the pixel driving circuit further includes a driving transistor, and the driving transistor is located in the first transistor distribution sub-layer. A source transfer pattern of the driving transistor is located in the fourth gate film layer, and the source transfer pattern of the driving transistor is connected to an anode transfer pattern of the anode transfer patterns.

In some embodiments, the pixel driving circuit further includes a sensing transistor, and the sensing transistor is located in the second transistor distribution sub-layer. The second source-drain metal layer further includes first sensing signal lines, and an active layer pattern of the sensing transistor is connected to a first sensing signal line of the first sensing signal lines.

In some embodiments, an active film layer of the first transistor distribution sub-layer is a polysilicon active film layer, and an active film layer of the second transistor distribution sub-layer is an oxide active film layer.

In some embodiments, the transistor distribution layer includes a first transistor distribution sub-layer, a second transistor distribution sub-layer, and a third transistor distribution sub-layer that are stacked in sequence, and the first transistor distribution sub-layer is closer to the base substrate than the second transistor distribution sub-layer.

The transistor distribution layer further includes a fourth gate film layer located between the first transistor distribution sub-layer and the second transistor distribution sub-layer.

The writing transistor is located in the second transistor distribution sub-layer. The drain transfer pattern of the writing transistor includes a first drain transfer pattern and a second drain transfer pattern. The first drain transfer pattern of the writing transistor is located in the fourth gate film layer, and the first drain transfer pattern of the writing transistor is connected to the second drain transfer pattern of the writing transistor and is connected to the data signal line.

The second drain transfer pattern of the writing transistor is located in a gate film layer of the second transistor distribution sub-layer, and the second drain transfer pattern of the writing transistor is connected to the active layer pattern of the writing transistor.

A source transfer pattern of the writing transistor is located in the gate film layer of the second transistor distribution sub-layer, and the source transfer pattern of the writing transistor is connected to the active layer pattern of the writing transistor.

In some embodiments, the pixel driving circuit further includes a driving transistor and a sensing transistor; the driving transistor is located in the first transistor distribution sub-layer, and the sensing transistor is located in the third transistor distribution sub-layer.

In some embodiments, the third transistor distribution sub-layer includes a third active film layer and a third gate film layer, and the third active film layer is closer to the base substrate than the third gate film layer.

A source transfer pattern of the driving transistor includes a first source transfer pattern and a second source transfer pattern. The first source transfer pattern of the driving transistor is located in the fourth gate film layer, and the second source transfer pattern of the driving transistor is located in the gate film layer of the second transistor distribution sub-layer. The first source transfer pattern of the driving transistor is connected to an active layer pattern of the driving transistor, and the second source transfer pattern of the driving transistor is connected to the first source transfer pattern of the driving transistor and is connected to an anode transfer pattern of the anode transfer patterns.

In some embodiments, the third transistor distribution sub-layer includes a third active film layer and a third gate film layer, and the third active film layer is farther away from the base substrate than the third gate film layer.

The second transistor distribution sub-layer includes a second active film layer and a second gate film layer, and the second active film layer is closer to the base substrate than the second gate film layer.

The third gate film layer and the second gate film layer are a same film layer. A source transfer pattern of the driving transistor is located in the fourth gate film layer, and the source transfer pattern of the driving transistor is connected to an anode transfer pattern of the anode transfer patterns.

In some embodiments, the second source-drain metal layer further includes first voltage signal lines. An active layer pattern of the driving transistor is connected to a first voltage signal line of the first voltage signal lines through a drain transfer pattern of the driving transistor. The drain transfer pattern of the driving transistor is located in the fourth gate film layer.

In some embodiments, the array substrate further includes a third source-drain metal layer located on a side of the second source-drain metal layer away from the base substrate. The second source-drain metal layer further includes sensing patterns, and an active layer pattern of the sensing transistor is connected to a sensing pattern of the sensing patterns. The third source-drain metal layer includes first sensing signal lines, and a first sensing signal line is connected to the sensing pattern.

In some embodiments, an active film layer of the first transistor distribution sub-layer is a polysilicon active film layer, and an active film layer of the second transistor distribution sub-layer and an active film layer of the third transistor distribution sub-layer are both oxide active film layers.

In some embodiments, the transistor distribution layer includes a first transistor distribution sub-layer, a second transistor distribution sub-layer, and a third transistor distribution sub-layer that are stacked, and the first transistor distribution sub-layer is closer to the base substrate than the second transistor distribution sub-layer.

The writing transistor is located in the first transistor distribution sub-layer. The drain transfer pattern of the writing transistor is located in a gate film layer of the second transistor distribution sub-layer, or the drain transfer pattern of the writing transistor is located in a gate film layer of the first transistor distribution sub-layer. A source transfer pattern of the writing transistor is located in the gate film layer of the second transistor distribution sub-layer, and the source transfer pattern of the writing transistor is connected to the active layer pattern of the writing transistor.

In some embodiments, the pixel driving circuit further includes a driving transistor and a sensing transistor; the driving transistor is located in the second transistor distribution sub-layer, and the sensing transistor is located in the third transistor distribution sub-layer.

The second source-drain metal layer further includes first sensing signal lines, and an active layer pattern of the sensing transistor is connected to a first sensing signal line of the first sensing signal lines.

In some embodiments, the third transistor distribution sub-layer includes a third active film layer and a third gate film layer, and the third active film layer is closer to the base substrate than the third gate film layer; or the third transistor distribution sub-layer includes a third active film layer and a third gate film layer, and the third active film layer is farther away from the base substrate than the third gate film layer. The transistor distribution layer further includes a fourth gate film layer located between the second transistor distribution sub-layer and the third active film layer, and the fourth gate film layer and the third gate film layer are a same film layer.

A source transfer pattern of the driving transistor is located in the fourth gate film layer, and the source transfer pattern of the driving transistor is connected to an anode transfer pattern of the anode transfer patterns.

In some embodiments, an active film layer of the first transistor distribution sub-layer, an active film layer of the second transistor distribution sub-layer and an active film layer of the third transistor distribution sub-layer are all oxide active film layers.

In some embodiments, the array substrate further includes a light-shielding layer.

The light-shielding layer is located on a side of the first source-drain metal layer close to the base substrate, or the light-shielding layer is located on a side of the first source-drain metal layer away from the base substrate.

At least one transistor disposed in a transistor distribution sub-layer in the transistor distribution layer closest to the base substrate is a dual-gate transistor. A gate film layer of the transistor distribution sub-layer closest to the base substrate is located on a side of an active film layer of the transistor distribution sub-layer away from the base substrate, and the gate film layer includes a top gate pattern of the dual-gate transistor. The light-shielding layer includes a bottom gate pattern of the dual-gate transistor.

In another aspect, a display panel is provided, which includes the array substrate as described in any one of the above embodiments and an anode layer disposed on the array substrate. The anode layer is connected to the anode transfer patterns.

In yet another aspect, a display apparatus is provided, which includes the display panel as described in the above embodiments.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art can obtain other drawings according to these drawings.

In addition, the accompanying drawings to be described below may be regarded as schematic diagrams, and are not limitations on actual sizes of products, actual processes of methods and actual timings of signals involved in the embodiments of the present disclosure.

FIG. 1 is a structural diagram of a display apparatus, in accordance with some embodiments of the present disclosure;

FIG. 2 is a structural diagram of a display panel, in accordance with some embodiments of the present disclosure;

FIG. 3 is a structural diagram of an array substrate, in accordance with some embodiments of the present disclosure;

FIG. 4 is an equivalent circuit diagram of a pixel driving circuit, in accordance with some embodiments of the present disclosure;

FIG. 5 is a structural diagram of an array substrate, in accordance with the related art;

FIG. 6 is a structural diagram of another array substrate, in accordance with some embodiments of the present disclosure;

FIG. 7 is a structural diagram of yet another array substrate, in accordance with some embodiments of the present disclosure;

FIG. 8 is a structural diagram of yet another array substrate, in accordance with some embodiments of the present disclosure;

FIG. 9A is a structural diagram of yet another array substrate, in accordance with some embodiments of the present disclosure;

FIG. 9B is a plan view showing a structure of a first source-drain metal layer of the array substrate shown in FIG. 9A;

FIG. 9C is a plan view showing a structure of a first active film layer of the array substrate shown in FIG. 9A;

FIG. 9D is a plan view showing a structure of a first gate film layer of the array substrate shown in FIG. 9A;

FIG. 9E is a plan view showing a structure of a third gate insulating layer of the array substrate shown in FIG. 9A;

FIG. 9F is a plan view showing a structure of a fourth gate film layer of the array substrate shown in FIG. 9A;

FIG. 9G is a plan view showing a structure of a second active film layer of the array substrate shown in FIG. 9A;

FIG. 9H is a plan view showing a structure of a fourth gate insulating layer of the array substrate shown in FIG. 9A;

FIG. 9I is a plan view showing a structure of a second gate film layer of the array substrate shown in FIG. 9A;

FIG. 9J is a plan view showing a structure of a third active film layer of the array substrate shown in FIG. 9A;

FIG. 9K is a plan view showing a structure of a third gate film layer of the array substrate shown in FIG. 9A;

FIG. 9L is a plan view showing a structure of an interlayer dielectric layer of the array substrate shown in FIG. 9A;

FIG. 9M is a plan view showing a structure of a second source-drain metal layer of the array substrate shown in FIG. 9A;

FIG. 9N is a plan view showing a structure of a planarization layer in FIG. 9A;

FIG. 9O is a structural diagram of stacked film layers of the array substrate shown in FIG. 9A;

FIG. 9P is a structural diagram of a stacked film layer layout of the array substrate shown in FIG. 9A;

FIG. 10 is a structural diagram of yet another array substrate, in accordance with some embodiments of the present disclosure;

FIG. 11 is a structural diagram of yet another array substrate, in accordance with some embodiments of the present disclosure;

FIG. 12 is a structural diagram of yet another array substrate, in accordance with some embodiments of the present disclosure;

FIG. 13 is a structural diagram of yet another array substrate, in accordance with some embodiments of the present disclosure;

FIG. 14 is a structural diagram of yet another array substrate, in accordance with some embodiments of the present disclosure;

FIG. 15 is a structural diagram of yet another array substrate, in accordance with some embodiments of the present disclosure;

FIG. 16 is a structural diagram of yet another array substrate, in accordance with some embodiments of the present disclosure;

FIG. 17 is a structural diagram of yet another array substrate, in accordance with some embodiments of the present disclosure;

FIG. 18A is a structural diagram of a drain transfer pattern of a driving transistor, in accordance with some embodiments of the present disclosure;

FIG. 18B is another structural diagram of a drain transfer pattern of a driving transistor, in accordance with some embodiments of the present disclosure;

FIG. 19A is yet another structural diagram of a drain transfer pattern of a driving transistor, in accordance with some embodiments of the present disclosure;

FIG. 19B is yet another structural diagram of a drain transfer pattern of a driving transistor, in accordance with some embodiments of the present disclosure;

FIG. 20A is yet another structural diagram of a drain transfer pattern of a driving transistor, in accordance with some embodiments of the present disclosure; and

FIG. 20B is another structural diagram of a drain transfer pattern of a driving transistor, in accordance with some embodiments of the present disclosure.

### DESCRIPTION OF THE INVENTION

Technical solutions in some embodiments of the present disclosure will be described clearly and completely below with reference to the accompanying drawings. Obviously, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

In the description of some embodiments, the terms such as “coupled” and “connected” and derivatives thereof may be used. The term “connected” should be understood in a broad sense. For example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, and they both include following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if”, depending on the context, is optionally construed as “when”, “in a case where”, “in response to determining”, or “in response to detecting” Similarly, depending on the context, the phrase “if it is determined” or “if [a stated condition or event] is detected” is optionally construed as “in a case where it is determined”, “in response to determining”, “in a case where [the stated condition or event] is detected”, or “in response to detecting [the stated condition or event]”.

The phrase “applicable to” or “configured to” as used herein indicates an open and inclusive expression, which does not exclude devices that are applicable to or configured to perform additional tasks or steps.

In addition, the phrase “based on” as used herein is meant to be open and inclusive, since a process, step, calculation or other action that is “based on” one or more of the stated conditions or values may, in practice, be based on additional conditions or values beyond those stated.

As used herein, the term such as “about”, “substantially” or “approximately” includes a stated value and an average value within an acceptable range of deviation of a particular value. The acceptable range of deviation is determined by a person of ordinary skill in the art in view of the measurement in question and errors associated with the measurement of a particular quantity (i.e., the limitation of the measurement system).

As used herein, the term such as “parallel”, “perpendicular”, or “equal” includes a stated condition and a condition similar to the stated condition. A range of the similar condition is in an acceptable range of deviation, and the acceptable range of deviation is determined by a person of ordinary skill in the art in view of measurement in question and errors associated with the measurement of a particular quantity (i.e., the limitation of the measurement system). For example, the term “parallel” includes absolute parallelism and approximate parallelism, and an acceptable range of deviation of the approximate parallelism may be, for example, a deviation within 5°. The term “perpendicular” includes absolute perpendicularity and approximate perpendicularity, and an acceptable range of deviation of the approximate perpendicularity may also be, for example, a deviation within 5°. The term “equal” includes absolute equality and approximate equality, and an acceptable range of deviation of the approximate equality may be, for example, a difference between two equals being less than or equal to 5% of either of the two equals.

It should be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of regions in an apparatus, and are not intended to limit the scope of the exemplary embodiments.

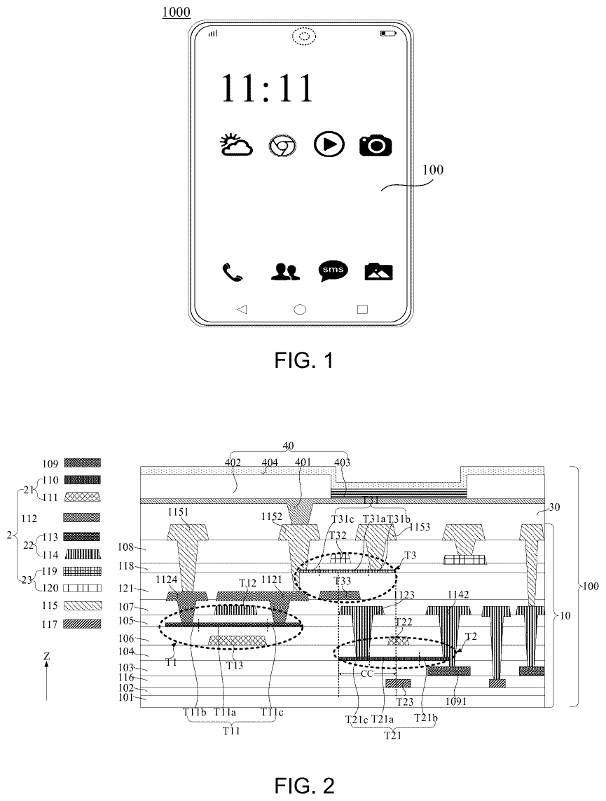

As shown in FIG. 1, some embodiments of the present disclosure provide a display apparatus 1000. The display apparatus 1000 may be any product or component having a display function such a television, a display, a notebook computer, a tablet computer, a mobile phone or a navigator. FIG. 1 is illustrated by taking an example in which the display apparatus 1000 is a mobile phone.

For example, the display apparatus 1000 may be any apparatus that displays images whether in motion (e.g., videos) or stationary (e.g., static images), and whether textual or graphical. More specifically, it is expected that the embodiments may be implemented in or associated with a variety of electronic apparatuses. The variety of electronic apparatuses may include (but are not limited to), for example, mobile phones, wireless apparatuses, personal digital assistants (PDAs), hand-held or portable computers, global positioning system (GPS) receivers/navigators, cameras, MP4 video players, video cameras, game consoles, watches, clocks, calculators, television monitors, flat panel displays, computer monitors, car displays (such as odometer displays), navigators, cockpit controllers and/or displays, camera view displays (such as rear view camera displays in vehicles), electronic photos, electronic billboards or indicators, projectors, building structures, packagings and aesthetic structures (such as a display for an image of a piece of jewelry), etc.

For example, the display apparatus 1000 may be an electroluminescent display apparatus or a photoluminescent display apparatus. In the case where the display apparatus 1000 is the electroluminescent display apparatus, the electroluminescent display apparatus may be an organic light-emitting diode (OLED) display apparatus or a quantum dot light-emitting diode (QLED) display apparatus. In the case where the display apparatus 1000 is the photoluminescent display apparatus, the photoluminescent display apparatus may be a quantum dot photoluminescent display apparatus.

Some embodiments of the present disclosure will be illustratively described below by taking an example in which the display apparatus 1000 is an OLED display apparatus, but the implementations of the present disclosure include but are not limited to this, and any other display apparatus may also be considered as long as the same technical concept is applied.

With continued reference to FIG. 1, the display apparatus 1000 includes a display panel 100.

Since the embodiments of the present disclosure are described by taking the display apparatus 1000 as the OLED display apparatus as an example, in the case where the display apparatus 1000 is the OLED display apparatus, the display panel 100 is an OLED display panel. However, the type of the display panel 100 is not limited thereto, and may also be any other display panel 100 using the following structure. In addition, the display panel 100 may be a transparent display panel, and the display panel 100 may be applied to the virtual reality (VR) technology. In a case where the display panel 100 in the embodiments of the present disclosure is applied to a VR apparatus, an image viewed by the human eye through the VR apparatus having the display panel 100 is a virtual image.

For example, the display panel 100 may be a flexible display panel, and its substrate is made of a flexible material. The flexible material may be made of a polymer material such as polyethylene terephthalate, polyarylethersulfone, polyethylene naphthalate, or polyimide. It should be noted that, the present disclosure does not specifically limit the material of the flexible substrate. No matter what material is selected (including selected from all flexible materials for flexible substrates in the prior art), it needs to have a certain degree of stretchability to form a flexible display substrate. In a specific preparation process, it is necessary to select a flexible material that meets the stretchability requirement according to the actual requirements for the display panel 100.

A structure of the display panel 100 will be described in detail below.

As shown in FIG. 2, FIG. 2 is a structural diagram of a display panel 100 provided in some embodiments of the present disclosure. The display panel 100 includes an array substrate 10, a planarization layer 30, a light-emitting device layer 40, and an encapsulation layer (not shown in the figure) that are stacked in sequence.

The encapsulation layer is located on a side of a cathode layer away from the array substrate 10. For example, the encapsulation layer may include a first inorganic encapsulation layer, an organic encapsulation layer and a second inorganic encapsulation layer. The encapsulation layer is used to encapsulate the light-emitting device layer 40 to protect the light-emitting device layer 40 from corrosion caused by external moisture and oxygen.

The light-emitting device layer 40 includes an anode layer 401, a pixel defining layer 402, a light-emitting layer 403, and a cathode layer 404. The anode layer 401 is disposed on a side of the planarization layer 30 away from the array substrate 10, and the anode layer 401 includes a plurality of anodes 4011. The light-emitting layer 403 includes a plurality of light-emitting portions, each of which overlaps with one anode 4011. The pixel defining layer 402 is provided with a plurality of pixel openings therein, each pixel opening exposes a portion of one anode 4011, and the light-emitting portions in the light-emitting layer 403 are arranged in the pixel openings in one-to-one correspondence, so that an edge of the light-emitting portion coincides with an edge of the pixel opening. The cathode layer 404 is located on a side of the pixel defining layer 402 and the light-emitting layers 403 away from the array substrate 10.

The planarization layer 30 is mainly used to block moisture and oxygen, and alkaline ions; and it can be obtained by coating PI (Polyimide) using a spin coating process, or obtained by depositing silicon nitride, silicon oxide or silicon oxynitride using a PECVD process.

The array substrate 10 includes anode transfer patterns 1152, and the anode transfer patterns 1152 are connected to the anode layer 401 through via holes penetrating the planarization layer 30.

A structure of the array substrate 10 will be described in detail below.

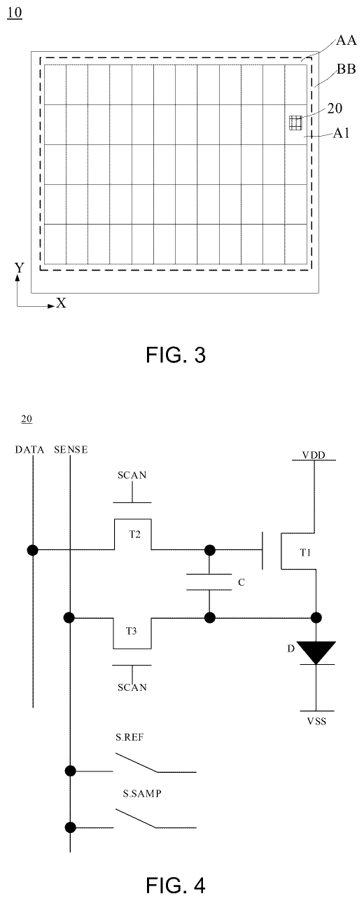

As shown in FIG. 3, the array substrate 10 includes a display area AA and a peripheral area BB located on at least one side of the display area AA. A plurality of sub-pixel regions A1 are disposed in the display area AA, and the plurality of sub-pixel regions A1 are arranged in the display area AA according to a specified rule. Each sub-pixel region A1 is provided with a pixel driving circuit 20 therein.

For example, the plurality of sub-pixel regions A1 are arranged in multiple rows and multiple columns. Since each sub-pixel region A1 is provided with a pixel driving circuit 20 therein, the pixel driving circuits 20 are also arranged in multiple rows and multiple columns.

The pixel driving circuit 20 includes a plurality of transistors. As shown in FIG. 4, FIG. 4 is a schematic diagram showing an equivalent circuit of a pixel driving circuit 20 provided in some embodiments of the present disclosure. It should be noted that, FIG. 4 is illustrated by taking an example in which the pixel driving circuit 20 is of a 3T1C structure, but a structure of the pixel driving circuit 20 in the embodiments of the present disclosure is not limited to this. For example, the pixel driving circuit 20 may be of a structure of 4T1C, 5T1C, 5T2C, 6T1C, 7T1C or 8T1C. “T” represents a transistor, a number before “T” represents the number of transistors, “C” represents a capacitor, and a number before “C” represents the number of capacitors.

With continued reference to FIG. 4, the pixel driving circuit 20 includes three transistors and one storage capacitor C. The three transistors are a driving transistor T1, a writing transistor T2 and a sensing transistor T3.

For example, the driving transistor T1, the writing transistor T2 and the sensing transistor T3 in the pixel driving circuit 20 may be low-temperature polysilicon transistors or oxide transistors, or may include low-temperature polysilicon transistors and oxide transistors. An active layer of the low-temperature polysilicon transistor is made of low-temperature polysilicon (LTPS), and an active layer of the oxide transistor is made of oxide semiconductor (Oxide). Low-temperature polysilicon transistors have the advantages of high mobility and fast charging, and oxide transistors have the advantages of low leakage current. Low-temperature polysilicon transistors and oxide transistors are integrated into the array substrate 10 to form a low-temperature polycrystalline oxide (LTPO) array substrate. By utilizing the advantages of the low-temperature polysilicon transistors and the oxide transistors, the refresh frequency of the array substrate 10 may be switched to achieve low-frequency driving, which is beneficial to reducing power consumption and improving display quality.

For example, the driving transistor T1, the writing transistor T2 and the sensing transistor T3 may be top-gate transistors, bottom-gate transistors, or dual-gate transistors. The dual-gate transistor includes an active layer pattern and a top gate pattern and a bottom gate pattern that are disposed on both sides of the active layer pattern. By driving the active layer pattern through the top gate pattern and the bottom gate pattern, the threshold voltage may be easily controlled, and the carrier mobility may also be improved. That is, compared with the top-gate transistor and bottom-gate transistor, the dual-gate transistor has a relatively high stability.

For example, the driving transistor T1, the writing transistor T2 and the sensing transistor T3 may be P-type transistors or N-type transistors. For example, the driving transistor T1, the writing transistor T2 and the sensing transistor T3 may include a P-type transistor and an N-type transistor. For another example, the driving transistor T1, the writing transistor T2 and the sensing transistor T3 may all be N-type transistors or P-type transistors. By using the same type of transistors in the pixel driving circuit 20, the process may be simplified, the process difficulty of the array substrate 10 may be reduced, and the yield of products may be improved. Some embodiments of the present disclosure will be illustratively described below by taking an example in which the driving transistor T1, the writing transistor T2 and the sensing transistor T3 are all N-type transistors, but the implementations of the present disclosure include but are not limited to this, and any other type of transistors can also be considered as long as the same technical concept is applied.

The connection of the driving transistor T1, the writing transistor T2, the sensing transistor T3, the storage capacitor C, and signal lines in the pixel driving circuit 20 shown in FIG. 4 is schematically described below.

A drain of the driving transistor T1 is connected to a first voltage signal line VDD, a source of the driving transistor T1 is connected to an anode of a light-emitting device D, and a gate of the driving transistor T1 is connected to a source of the writing transistor T2; a drain of the writing transistor T2 is connected to a data signal line DATA, the source of the writing transistor T2 is connected to the gate of the driving transistor T1 and one end of the storage capacitor C, and a gate of the writing transistor T2 is connected to a scan signal line SCAN; a drain of the sensing transistor T3 is connected to a sensing signal line SENSE, a source of the sensing transistor T3 is connected to the anode of the light-emitting device D and the other end of the storage capacitor C, and a gate of the sensing transistor T3 is connected to the scan signal line.

The pixel driving circuit 20 is disposed in the film layer structure of the array substrate 10. The structure of film layers included in the array substrate 10 and the arrangement of transistors in the pixel driving circuit 20 are described below.

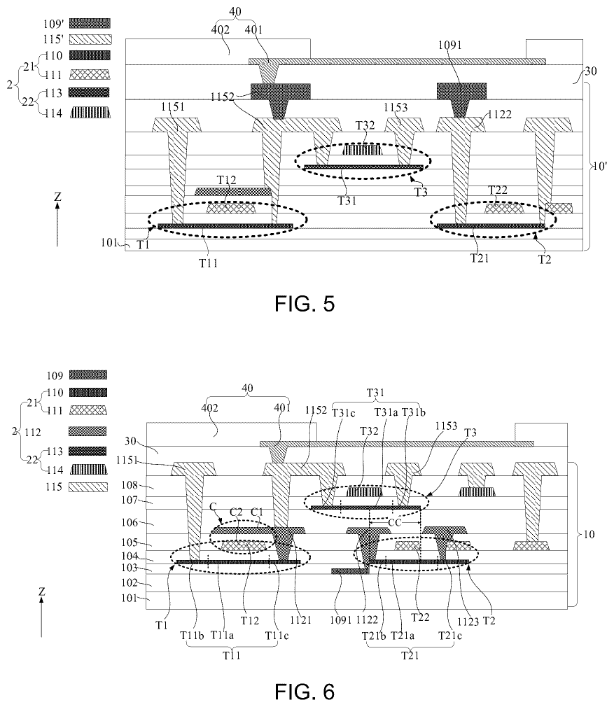

As shown in FIG. 5, FIG. 5 is a structural diagram of an array substrate 10′ in the related art. The array substrate 10′ includes a base substrate 101, a transistor distribution layer 2, a second source-drain metal layer 115′, and a first source-drain metal layer 109′ that are stacked in sequence.

The first source-drain metal layer 109′ includes data signal lines 1091 and anode transfer patterns 1152. The second source-drain metal layer 115′ includes first drain transfer patterns 1122 of writing transistors T2 and the anode transfer patterns 1152. It can be understood that the anode transfer patterns 1152 are distributed in two metal layers.

The driving transistor T1, the writing transistor T2 and the sensing transistor T3 of the pixel driving circuit 20 are disposed in the transistor distribution layer 2. The transistor distribution layer 2 includes an active layer pattern T11 of the driving transistor T1 and an active layer pattern T21 of the writing transistor T2.

The active layer pattern T21 of the writing transistor T2 needs to be electrically connected to a data signal line 1091 in the first source-drain metal layer 109′ through a via hole and the first drain transfer pattern 1122 of the writing transistor T2 in the second source-drain metal layer 115′, and the active layer pattern T11 of the driving transistor T1 is electrically connected to the anode transfer pattern in the second source-drain metal layer 115′ and the anode transfer pattern in the first source-drain metal layer 109′. The first source-drain metal layer 109′ is provided therein with a plurality of signal lines and a plurality of transfer patterns, e.g., the data signal lines 1091 and the anode transfer patterns 1152, and the second source-drain metal layer 115′ is also provided therein with a plurality of signal lines and a plurality of transfer patterns, e.g., the first drain transfer patterns 1122 of the writing transistors T2 and the anode transfer patterns 1152, which results in an increase in the wiring difficulty of the first source-drain metal layer 109′ and the second source-drain metal layer 115′, and a decrease in the number of pixel driving circuits 20 arranged in the array substrate 10′. In addition, the active layer pattern T21 of the writing transistor T2 needs to be electrically connected to the data signal line 1091 in the first source-drain metal layer 109′ through a via hole, and the active layer pattern T11 of the driving transistor T1 also needs to be sequentially electrically connected to the anode transfer pattern in the second source-drain metal layer 115′ and the anode transfer pattern in the first source-drain metal layer 109′ through another via hole. The above two via holes (for the convenience of description, they are collectively referred to as same-direction via holes below) are located on the same side of the active layer patterns of the corresponding transistors (the writing transistor T2 and the driving transistor T1), which results in the large number of same-direction via holes in the array substrate 10. Since active layer patterns of the transistors in the sub-pixel region A1 need not overlap with each other, space for arranging the plurality of same-direction via holes needs to be reserved, resulting in a large space occupied by the pixel driving circuit 20. Thus, the number of pixel driving circuits 20 arranged in the array substrate 10′ is further reduced, which is not beneficial to achieving high PPI (pixels per inch, pixel density) of the display panel 100.

Based on this, as shown in FIGS. 6 to 9A and 10 to 17, FIGS. 6 to 9A and 10 to 17 are structural diagrams of an array substrate 10 in accordance with some embodiments of the present disclosure. The array substrate 10 includes a base substrate 101, a first source-drain metal layer 109, a transistor distribution layer 2, and a second source-drain metal layer 115 that are stacked in sequence. That is, the first source-drain metal layer 109 and the second source-drain metal layer 115 are disposed on opposite sides of the transistor distribution layer 2, and the first source-drain metal layer 109 is closer to the base substrate 101 than the second source-drain metal layer 115.

For example, the base substrate 101 may be a hard substrate made of a light-conducting and non-metallic material with a certain degree of firmness, such as glass, quartz or common resin; or the base substrate 101 may be a flexible substrate made of a flexible material such as polyimide (PI).

The first source-drain metal layer 109 includes data signal lines 1091, and the second source-drain metal layer 115 includes anode transfer patterns 1152. For example, the first source-drain metal layer 109 and the second source-drain metal layer 115 are obtained by depositing a metal material such as MO/Ti/AI/Cu (molybdenum/titanium/aluminum/copper) using a PVD (physical vapor deposition) process.

The writing transistors T2 are disposed in the transistor distribution layer 2, and the writing transistor T2 includes an active layer pattern T21 of the writing transistor T2 and a gate pattern T22 of the writing transistor T2. The active layer pattern T21 of the writing transistor T2 includes a source region T21c of the writing transistor T2, a drain region T21b of the writing transistor T2, and a channel region T21a of the writing transistor T2 located between the source region T21c and the drain region T21b of the writing transistor T2.

The active layer pattern T21 of the writing transistor T2 is electrically connected to the data signal line 1091. Specifically, the drain region T21b in the active layer pattern T21 of the writing transistor T2 is electrically connected to the data signal line 1091.

By arranging the first source-drain metal layer 109 and the second source-drain metal layer 115 on opposite sides of the transistor distribution layer 2, i.e., making the second source-drain metal layer 115 not arranged between the first source-drain metal layer 109 and the transistor distribution layer 2, the electrical connection between the active layer pattern T21 of the writing transistor T2 in the transistor distribution layer 2 and the data signal line 1091 in the first source-drain metal layer 109 does not need to rely on the second source-drain metal layer 115. Therefore, there is no need to provide a first drain transfer pattern 1122 of the writing transistor T2 in the second source-drain metal layer 115, which may reduce the wiring difficulty of the second source-drain metal layer 115, may increase the number of pixel driving circuits 20 arranged in the array substrate 10 in the same area as the array substrate 10′ shown in FIG. 5, and may be beneficial to improving the PPI (pixels per inch, pixel density) of the display panel 100. Furthermore, the electrical connection between the anode transfer pattern 1152 in the second source-drain metal layer 115 and the anode layer 401 in the light-emitting device layer 40 does not need to rely on the first source-drain metal layer 109. Therefore, there is no need to provide the anode transfer pattern 1152 in the first source-drain metal layer 109, which may reduce the wiring difficulty of the first source-drain metal layer 109, may increase the number of pixel driving circuits 20 arranged in the same area of the array substrate 10 as the array substrate 10′ shown in FIG. 5, and may be beneficial to improving the PPI (pixels per inch, pixel density) of the display panel 100.

In addition, the active layer pattern T21 of the writing transistor T2 is electrically connected to the data signal line 1091 in the first source-drain metal layer 109 through a via hole facing the base substrate 101, and the active layer pattern T11 of the driving transistor T1 is electrically connected to the anode transfer pattern in the second source-drain metal layer 109 through another via hole facing the side away from the base substrate 101. The above two via holes are located on both sides of active layer patterns of the corresponding transistors (the writing transistor T2 and the driving transistor T1), that is, they are not same-direction via holes, which may reduce the number of same-direction via holes in the array substrate 10, and may be beneficial to increasing the number of pixel driving circuits 20 arranged in the array substrate 10. Thus, the PPI (pixels per inch, pixel density) of the display panel 100 is further improved.

It should be noted that, the above-mentioned “area of the array substrate 10” refers to a size of a horizontal region of the array substrate 10 on a reference plane (the reference plane is parallel to the base substrate 101 of the array substrate 10), i.e., an area of a region of an orthographic projection of the array substrate 10 on the reference plane. Similarly, the above-mentioned “area of the array substrate 10′” refers to a size of a horizontal region of the array substrate 10′ on the reference plane, i.e., an area of a region of an orthographic projection of the array substrate 10′ on the reference plane. The following description of “area of the array substrate 10” and “area of the array substrate 10′” also follows this description.

In some embodiments, with continued reference to FIGS. 6 to 9A and 10 to 17, the transistor distribution layer 2 includes at least two transistor distribution sub-layers and a fourth gate film layer 112 that are stacked, and the driving transistor T1, the writing transistor T2 and the sensing transistor T3 in the pixel driving circuit 20 are arranged in the at least two transistor distribution sub-layers. Each of the at least two transistor distribution sub-layers includes an active film layer and a gate film layer that are stacked; the active film layer includes an active layer pattern of the transistor, and the gate film layer includes a gate pattern of the transistor. That is, the driving transistor T1 includes an active layer pattern T11 and a gate pattern T12 of the driving transistor T1, the writing transistor T2 includes the active layer pattern T21 and the gate pattern T22 of the writing transistor T2, and the sensing transistor T3 includes an active layer pattern T31 and a gate pattern T32 of the sensing transistor T3. A first electrode plate C1 of the storage capacitor C in the pixel driving circuit 20 is disposed in the fourth gate film layer 112, and the gate pattern T12 of the driving transistor T1 also serves as a second electrode plate C2 of the storage capacitor C.

The active layer pattern T11 of the driving transistor T1 includes a source region T11c of the driving transistor T1, a drain region T11b of the driving transistor T1, and a channel region T11a of the driving transistor T1 located between the source region T11c of the driving transistor T1 and the drain region T11b of the driving transistor T1; the active layer pattern T21 of the writing transistor T2 includes a source region T21c of the writing transistor T2, a drain region T21b of the writing transistor T2, and a channel region T21a of the writing transistor T2 located between the source region T21c of the writing transistor T2 and the drain region T21b of the writing transistor T2; the active layer pattern T31 of the sensing transistor T3 includes a source region T31c of the sensing transistor T3, a drain region T31b of the sensing transistor T3, and a channel region T31a of the sensing transistor T3 located between the source region T31c of the sensing transistor T3 and the drain region T31b of the sensing transistor T3.

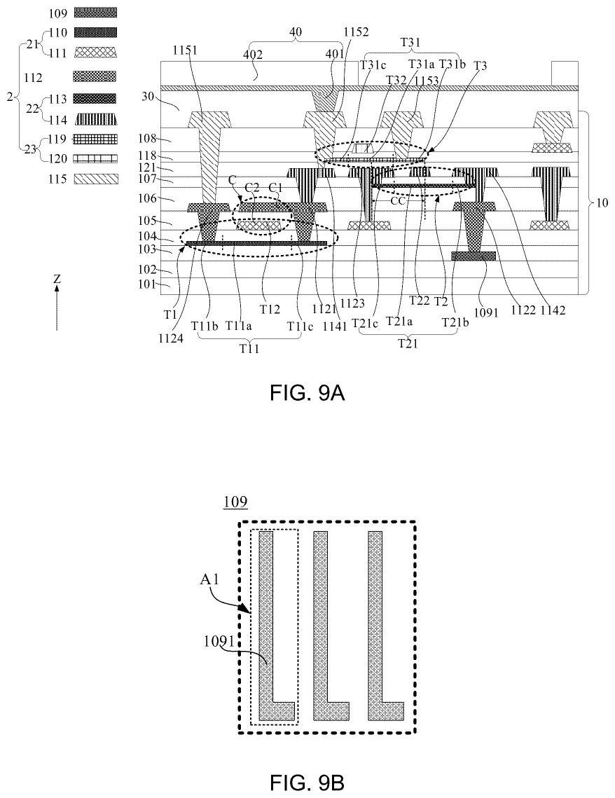

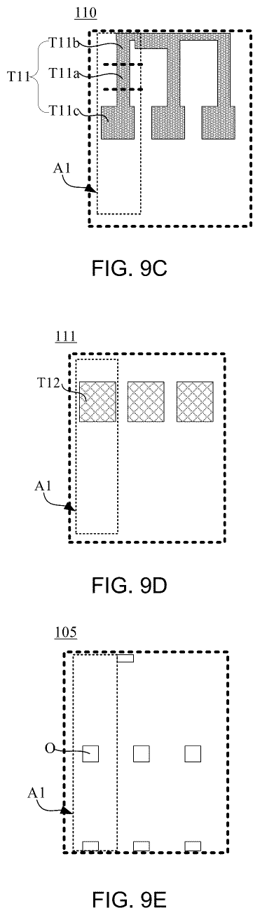

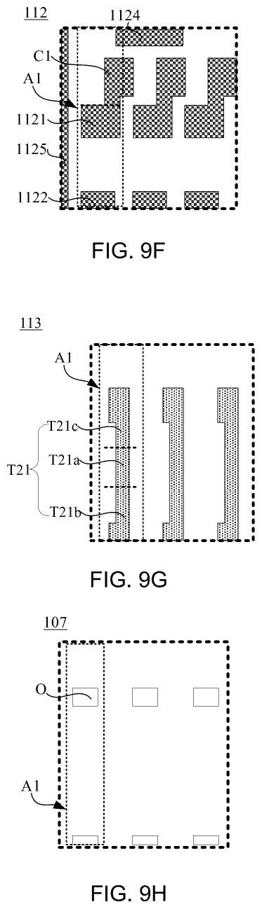

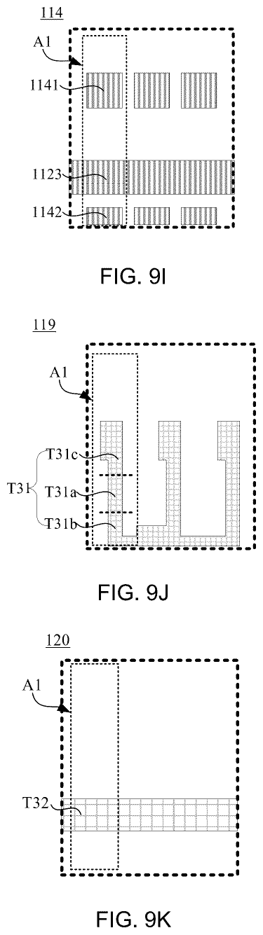

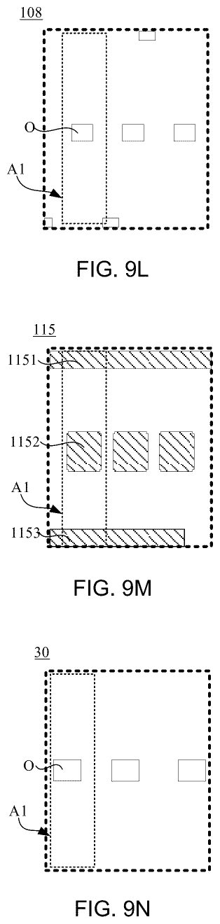

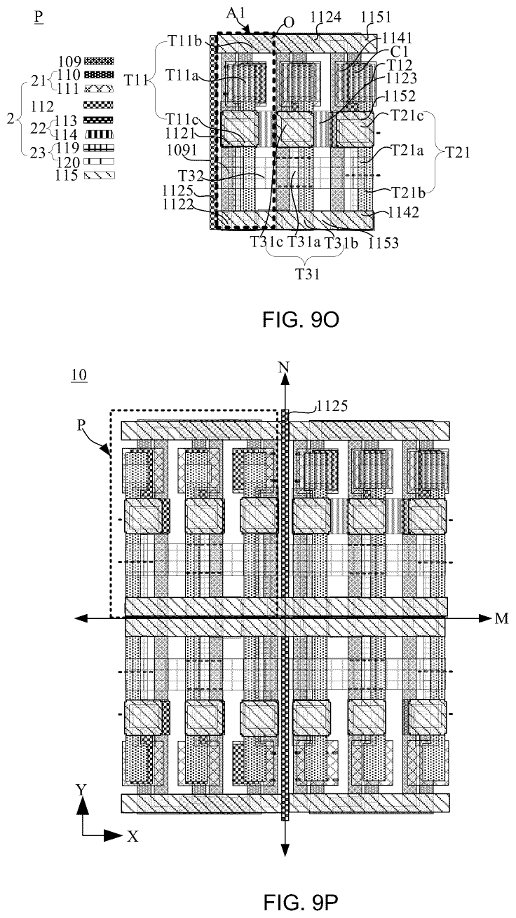

It should be noted that, the above description “the transistor distribution layer 2 includes at least two transistor distribution sub-layers that are stacked” means that the number of transistor distribution sub-layers in the transistor distribution layer 2 is greater than or equal to two. For example, as shown in FIGS. 6, 7 and 8, the number of transistor distribution sub-layers in the transistor distribution layer 2 is two, which include a first transistor distribution sub-layer 21 and a second transistor distribution sub-layer 22; or as shown in FIGS. 9A to 17, the number of transistor distribution sub-layers in the transistor distribution layer 2 is three, which include a first transistor distribution sub-layer 21, a second transistor distribution sub-layer 22, and a third transistor distribution sub-layer 23. Of course, the number of transistor distribution sub-layers in the transistor distribution layer 2 can also be four, five or six, etc., which can be set according to actual needs, and the present disclosure does not specifically limit thereto.

For example, for at least two transistors arranged in different transistor distribution sub-layers, orthographic projections of their active layer patterns on the base substrate 101 at least partially overlap, which may reduce a total area of orthographic projections of multiple transistors in a single pixel driving circuit 20 on the base substrate 101, and reduce an area of a single pixel driving circuit 20. Thus, the number of pixel driving circuits 20 in the array substrate 10 per unit area may be further increased, which is beneficial to further improving the PPI (pixels per inch, pixel density) of the display panel 100.

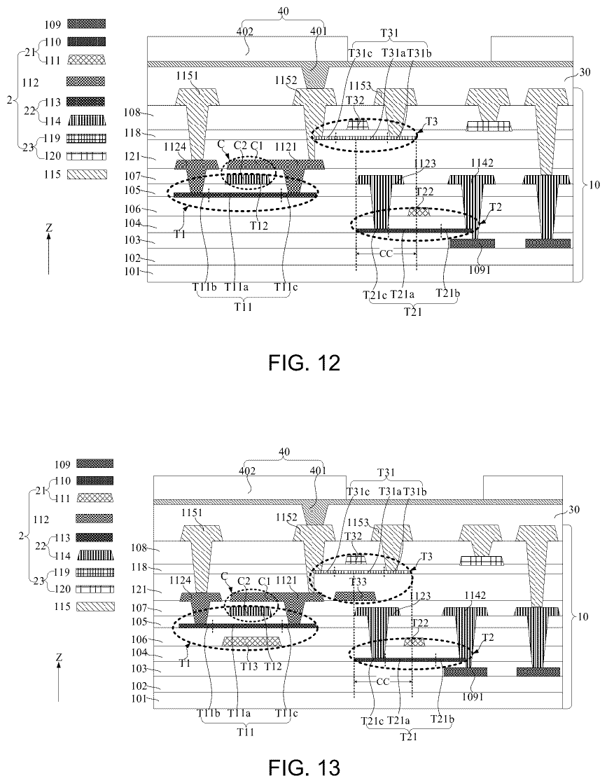

In some embodiments, with continued reference to FIGS. 6 to 9A and 10 to 17, the active layer pattern T21 of the writing transistor T2 is electrically connected to the data signal line 1091 in the first source-drain metal layer 109 through a drain transfer pattern of the writing transistor T2 (which includes, for example, a first drain transfer pattern 1122 of the writing transistor T2 in FIGS. 6 to 8, or a second drain transfer pattern 1142 of the writing transistor T2 in FIGS. 12 to 17, or a first drain transfer pattern 1122 and a second drain transfer pattern 1142 of the writing transistor T2 in FIGS. 9A, 10 and 11). Specifically, the drain region T21b of the active layer pattern T21 of the writing transistor T2 is electrically connected to the data signal line 1091 through the drain transfer pattern of the writing transistor T2. The drain transfer pattern of the writing transistor T2 is located in a first transfer gate film layer. That is, a film layer provided with the drain transfer pattern of the writing transistor T2 in the array substrate 10 serves as the first transfer gate film layer. The first transfer gate film layer may be located in the transistor distribution sub-layers and/or between two adjacent transistor distribution sub-layers. Compared with the situation where source transfer patterns/drain transfer patterns of transistors are all arranged in the second source-drain metal layer 115′ in FIG. 5, by using the film layer in the transistor distribution sub-layers and/or the film layer located between two adjacent transistor distribution sub-layers as the first transfer gate film layer in which the drain transfer pattern of the writing transistor T2 is arranged, i.e., by arranging the drain transfer pattern of the writing transistor T2 in a film layer located between the first source-drain metal layer 109 and the second source-drain metal layer 115, the wiring difficulty of other film layers (the second source-drain metal layer 115) in the array substrate 10 may be reduced, which is beneficial to further improving the PPI (pixels per inch, pixel density) of the display panel 100.

For example, there is one first transfer gate film layer in the array substrate 10. For example, the first transfer gate film layer is arranged between two adjacent transistor distribution sub-layers, or the gate film layer in one of the at least two transistor distribution sub-layers serves as the first transfer gate film layer. The number of first transfer gate film layers in the array substrate 10 may also be two; one first transfer gate film layer is arranged between two adjacent transistor distribution sub-layers, and the other first transfer gate film layer is the gate film layer in one of the at least two transistor distribution sub-layers.

In some embodiments, with continued reference to FIGS. 6 to 9A and 10 to 17, the active layer pattern T21 of the writing transistor T2 is connected to a source transfer pattern 1123 of the writing transistor T2. Specifically, the source region T21c of the active layer pattern T21 of the writing transistor T2 is connected to the source transfer pattern 1123 of the writing transistor T2. The source transfer pattern 1123 of the writing transistor T2 is located in a second transfer gate film layer. That is, a film layer provided with the source transfer pattern 1123 of the writing transistor T2 in the array substrate 10 serves as the second transfer gate film layer. The second transfer gate film layer is located in the transistor distribution sub-layers and/or between two adjacent transistor distribution sub-layers. Compared with the situation where source transfer patterns/drain transfer patterns of transistors are all arranged in the second source-drain metal layer 115′ in FIG. 5, by using the film layer in the transistor distribution sub-layers and/or the film layer located between two adjacent transistor distribution sub-layers as the second transfer gate film layer in which the source transfer pattern 1123 of the writing transistor T2 is arranged, i.e., by arranging the source transfer pattern 1123 of the writing transistor T2 in a film layer located between the first source-drain metal layer 109 and the second source-drain metal layer 115, the wiring difficulty of other film layers (the second source-drain metal layer 115) in the array substrate 10 may be reduced, which is beneficial to further improving the PPI (pixels per inch, pixel density) of the display panel 100.

For example, the second transfer gate film layer in the array substrate 10 is arranged between two adjacent transistor distribution sub-layers, or the gate film layer in one of the at least two transistor distribution sub-layers serves as the second transfer gate film layer.

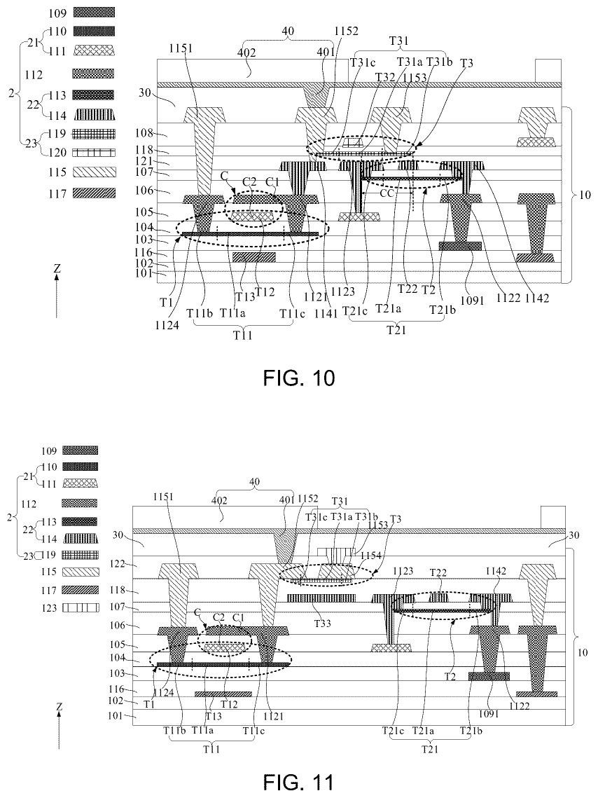

In some embodiments, with continued reference to FIGS. 6 to 9A and 10 to 17, the active layer pattern T31 of the sensing transistor T3 is electrically connected to the anode transfer pattern 1152. Specifically, the source region T31c of the active layer pattern T31 of the sensing transistor T3 is electrically connected to the anode transfer pattern 1152. The active layer pattern T11 of the driving transistor T1 is connected to the anode transfer pattern 1152 through a source transfer pattern of the driving transistor T1 (which includes, for example, a first source transfer pattern 1121 of the driving transistor T1 in FIGS. 6 to 8 and 11 to 17, or a first source transfer pattern 1121 and a second source transfer pattern 1141 of the driving transistor T1 in FIGS. 9A and 10). Specifically, the source region T11c of the active layer pattern T11 of the driving transistor T1 is connected to the anode transfer pattern 1152 through the source transfer pattern of the driving transistor T1.

The source transfer pattern of the driving transistor T1 is located in a third transfer gate film layer, and the third transfer gate film layer is located in the transistor distribution sub-layers and/or between two adjacent transistor distribution sub-layers. Compared with the situation where source transfer patterns/drain transfer patterns of transistors are all arranged in the second source-drain metal layer 115′ in FIG. 5, by using the film layer in the transistor distribution sub-layers and/or the film layer located between two adjacent transistor distribution sub-layers as the third transfer gate film layer in which the source transfer pattern of the driving transistor T1 is arranged, the wiring difficulty of other film layers (the second source-drain metal layer 115) in the array substrate 10 may be reduced, which is beneficial to further improving the PPI (pixels per inch, pixel density) of the display panel 100.

For example, there is one third transfer gate film layer in the array substrate 10. For example, the third transfer gate film layer is arranged between two adjacent transistor distribution sub-layers, or the gate film layer in one of the at least two transistor distribution sub-layers serves as the third transfer gate film layer. The number of third transfer gate film layers in the array substrate 10 may also be two; one third transfer gate film layer is arranged between two adjacent transistor distribution sub-layers, and the other third transfer gate film layer is the gate film layer in one of the at least two transistor distribution sub-layers.

Various embodiments of the present disclosure will be described below with reference to FIGS. 6 to 17.

It should be noted that, in the specification and drawings of the present disclosure, regarding the drawings that have already been given, the same symbol is used for the same elements as those described above, and the detailed description is appropriately omitted. The “Z” direction in FIGS. 6 to 9A and 10 to 17 refers to a thickness direction of the array substrate 10.

First, embodiments in which the transistor distribution layer 2 includes two transistor distribution sub-layers is described.

An array substrate shown in FIG. 6 will be introduced below. In some embodiments, as shown in FIG. 6, FIG. 6 is a structural diagram of the array substrate 10, in accordance with some embodiments of the present disclosure. The array substrate 10 includes the base substrate 101, a first buffer layer 102, a first source-drain metal layer 109, a first gate insulating layer 103, a first active film layer 110, a second gate insulating layer 104, a first gate film layer 111, a third gate insulating layer 105, a fourth gate film layer 112, a second buffer layer 106, a second active film layer 113, a fourth gate insulating layer 107, a second gate film layer 114, an interlayer dielectric layer 108, and a second source-drain metal layer 115 that are stacked in sequence.

The first active film layer 110 may be made of low-temperature polysilicon. The second active film layer 113 may be made of indium gallium zinc oxide or low-temperature polycrystalline oxide. For example, the second active film layer 113 may be made of IGZO (indium gallium zinc oxide) or IGZTO (indium gallium zinc tin oxide).

For example, the first active film layer 110 may be obtained by using an excimer laser annealing process, and the second active film layer 113 may be obtained by using a PVD (physical vapor deposition) process.

For example, the first buffer layer 102 and the second buffer layer 106 may be manufactured by PECVD (plasma enhanced chemical vapor deposition), and materials of the first buffer layer 102 and the second buffer layer 106 may be silicon nitride, silicon oxide or silicon oxynitride, which has the function of blocking moisture and gas.

For example, the first gate insulating layer 103, the second gate insulating layer 104, the third gate insulating layer 105, and the fourth gate insulating layer 107 may be made of silicon nitride, silicon oxide or silicon oxynitride, and may be deposited by a PECVD process.

For example, the first gate film layer 111, the fourth gate film layer 112, and the second gate film layer 114 may be obtained by depositing a metal material such as MO/Ti/AI/Cu (molybdenum/titanium/aluminum/copper) using a PVD process.

For example, a material of the interlayer dielectric layer 108 may be any one of silicon nitride, silicon oxide or silicon oxynitride, or may be a combination of any two of these materials; and the interlayer dielectric layer 108 may be deposited by using a PECVD process.

With continued reference to FIG. 6, the transistor distribution layer 2 includes the first transistor distribution sub-layer 21, the fourth gate film layer 112, and the second transistor distribution sub-layer 22 that are stacked. The first transistor distribution sub-layer 21 is closer to the base substrate 101 than the second transistor distribution sub-layer 22. That is, a distance between the first transistor distribution sub-layer 21 and the base substrate 101 is smaller than a distance between the second transistor distribution sub-layer 22 and the base substrate 101. The fourth gate film layer 112 is disposed between the first transistor distribution sub-layer 21 and the second transistor distribution sub-layer 22.

The first transistor distribution sub-layer 21 includes the first active film layer 110 and the first gate film layer 111. The driving transistor T1 and the writing transistor T2 of the pixel driving circuit 20 are arranged in the first transistor distribution sub-layer 21. Since the material of the first active film layer 110 is the low-temperature polysilicon, the driving transistor T1 and the writing transistor T2 are low-temperature polysilicon transistors.

The second transistor distribution sub-layer 22 includes the second active film layer 113 and the second gate film layer 114. The sensing transistor T3 of the pixel driving circuit 20 is arranged in the second transistor distribution sub-layer 22. Since the second active film layer 113 may be made of any one of indium gallium zinc oxide or low-temperature polycrystalline oxide, the sensing transistor T3 is an oxide transistor.

In the embodiments, the driving transistor T1 may be a top-gate transistor, which includes the active layer pattern T11 and the gate pattern T12 of the driving transistor T1. The active layer pattern T11 of the driving transistor T1 is arranged in the first active film layer 110, and the gate pattern T12 of the driving transistor is arranged in the first gate film layer 111.

In the embodiments, the writing transistor T2 may be a top-gate transistor, which includes the active layer pattern T21 and the gate pattern T22 of the writing transistor T2. The active layer pattern T21 of the writing transistor T2 is arranged in the first active film layer 110, and the gate pattern T22 of the writing transistor T2 is arranged in the first gate film layer 111.

In the embodiments, the sensing transistor T3 may be a top-gate transistor, which includes the active layer pattern T31 and the gate pattern T32 of the sensing transistor T3. The active layer pattern T31 of the sensing transistor T3 is arranged in the second active film layer 113, and the gate pattern T32 of the sensing transistor T3 is arranged in the second gate film layer 114.

The first source-drain metal layer 109 includes data signal lines 1091.

The fourth gate film layer 112 includes the first source transfer pattern 1121 of the driving transistor T1, the first drain transfer pattern 1122 of the writing transistor T2, and the source transfer pattern 1123 of the writing transistor T2. It should be noted that, in the embodiments, the fourth gate film layer 112 not only serves as the first transfer gate film layer, but also as the second transfer gate film layer and the third transfer gate film layer.

Compared with the situation where source transfer patterns/drain transfer patterns of transistors are all arranged in the second source-drain metal layer 115′ in an embodiment shown in FIG. 5, in the embodiments, the fourth gate film layer 112 simultaneously serves as the first transfer gate film layer, the second transfer gate film layer and the third transfer gate film layer, in which the first source transfer pattern 1121 of the driving transistor T1, the first drain transfer pattern 1122 of the writing transistor T2 and the source transfer pattern 1123 of the writing transistor T2 are arranged. Thus, the wiring difficulty of other film layers (the second source-drain metal layer 115) in the array substrate 10 may be reduced, which is conducive to further improving the PPI (pixels per Inch, pixel density) of the display panel 100.

The second source-drain metal layer 115 includes first voltage signal lines 1151, anode transfer patterns 1152, and first sensing signal lines 1153.

The active layer pattern T11 of the driving transistor T1 is connected to a first voltage signal line 1151 through a via hole. Specifically, the drain region T11b of the active layer pattern T11 of the driving transistor T1 is connected to the first voltage signal line 1151 through the via hole. The active layer pattern T11 of the driving transistor T1 is connected to an anode transfer pattern 1152 through a via hole and the first source transfer pattern 1121 of the driving transistor T1. Specifically, the source region T11c of the active layer pattern T11 of the driving transistor T1 is connected to the anode transfer pattern 1152 through the via hole and the first source transfer pattern 1121 of the driving transistor T1.

The active layer pattern T21 of the writing transistor T2 is electrically connected to a data signal line 1091 through a via hole and the first drain transfer pattern 1122 of the writing transistor T2. Specifically, the drain region T21b of the active layer pattern T21 of the writing transistor T2 is electrically connected to the data signal line 1091 through the via hole and the first drain transfer pattern 1122 of the writing transistor T2. The active layer pattern T21 of the writing transistor T2 is electrically connected to the gate pattern T12 of the driving transistor T1 through a via hole and the source transfer pattern 1123 of the writing transistor T2. Specifically, the source region T21c of the active layer pattern T21 of the writing transistor T2 is electrically connected to the gate pattern T12 of the driving transistor T1 through the via hole and the source transfer pattern 1123 of the writing transistor T2.

The active layer pattern T31 of the sensing transistor T3 is electrically connected to a first sensing signal line 1153 through a via hole. Specifically, the drain region T31b of the active layer pattern T31 of the sensing transistor T3 is electrically connected to the first sensing signal line 1153 through the via hole. The active layer pattern T31 of the sensing transistor T3 is electrically connected to the anode transfer pattern 1152 through a via hole. Specifically, the source region T31c of the active layer pattern T31 of the sensing transistor T3 is electrically connected to the anode transfer pattern 1152 through the via hole.

For example, in the Z direction, there is an overlapping region CC between the active layer pattern T21 of the writing transistor T2 arranged in the first transistor distribution sub-layer 21 and the active layer pattern T31 of the sensing transistor T3 arranged in the second transistor distribution sub-layer 22. That is, in a sub-pixel region A1, the writing transistor T2 and the sensing transistor T3 have an overlapping region CC. By setting the overlapping region CC, the area of the sub-pixel region A1 may be further reduced, which is beneficial to further improving the PPI of the array substrate 10.

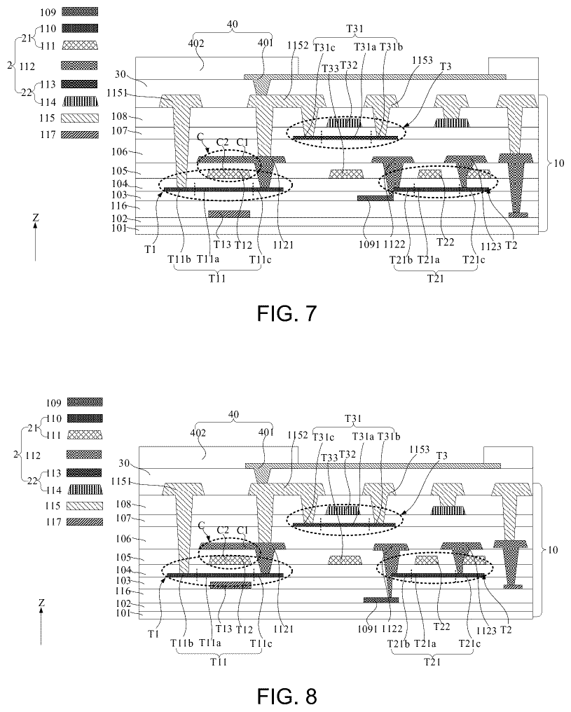

Array substrates 10 shown in FIGS. 7 and 8 will be introduced below. In some embodiments, as shown in FIGS. 7 and 8, FIGS. 7 and 8 are structural diagrams of the array substrates 10, in accordance with some embodiments of the present disclosure.

As shown in FIG. 7, the array substrate 10 includes the base substrate 101, a first buffer layer 102, a light-shielding layer 117, a third buffer layer 116, a first source-drain metal layer 109, a first gate insulating layer 103, a first active film layer 110, a second gate insulating layer 104, a first gate film layer 111, a third gate insulating layer 105, a fourth gate film layer 112, a second buffer layer 106, a second active film layer 113, a fourth gate insulating layer 107, a second gate film layer 114, an interlayer dielectric layer 108 and a second source-drain metal layer 115 that are stacked in sequence. The light-shielding layer 117 is located on a side of the first source-drain metal layer 109 proximate to the base substrate 101. That is, the light-shielding layer 117 is located between the first source-drain metal layer 109 and the base substrate 101.

Alternatively, as shown in FIG. 8, the array substrate 10 includes the base substrate 101, a first buffer layer 102, a first source-drain metal layer 109, a third buffer layer 116, a light-shielding layer 117, a first gate insulating layer 103, a first active film layer 110, a second gate insulating layer 104, a first gate film layer 111, a third gate insulating layer 105, a fourth gate film layer 112, a second buffer layer 106, a second active film layer 113, a fourth gate insulating layer 107, a second gate film layer 114, an interlayer dielectric layer 108 and a second source-drain metal layer 115 that are stacked in sequence. The light-shielding layer 117 is located on a side of the first source-drain metal layer 109 away from the base substrate 101. That is, the first source-drain metal layer 109 is located between the light-shielding layer 117 and the base substrate 101.

The light-shielding layer 117 can shield light directed to the array substrate 10 from a side of the base substrate 101 away from the light-shielding layer 117. The light-shielding layer 117 overlaps with the active layer pattern T11 of the driving transistor T1. Specifically, the light-shielding layer 117 overlaps with the channel region T11a of the active layer pattern T11 of the driving transistor T1. Thus, the light directed to the driving transistor T1 may be shielded, thereby preventing the properties of the driving transistor T1 from being changed by light. For example, a material of the light-shielding layer 117 may be amorphous silicon.

For example, the third buffer layer 116 may be manufactured by PECVD (plasma enhanced chemical vapor deposition), and the material thereof may be silicon nitride, silicon oxide or silicon oxynitride, which has the function of blocking moisture and gas.

The materials and manufacturing processes of the first active film layer 110, the second active film layer 113, the first buffer layer 102, the second buffer layer 106, the first gate insulating layer 103, the second gate insulating layer 104, the third gate insulating layer 105, the fourth gate insulating layer 107, the first gate film layer 111, the fourth gate film layer 112, the second gate film layer 114 and the interlayer dielectric layer 108 are basically the same as those in the embodiments shown in FIG. 6, which are not repeated here.

With continued reference to FIGS. 7 and 8, the transistor distribution layer 2 includes the first transistor distribution sub-layer 21, the fourth gate film layer 112, and the second transistor distribution sub-layer 22 that are stacked. The first transistor distribution sub-layer 21 is closer to the base substrate 101 than the second transistor distribution sub-layer 22. That is, a distance between the first transistor distribution sub-layer 21 and the base substrate 101 is smaller than a distance between the second transistor distribution sub-layer 22 and the base substrate 101. The fourth gate film layer 112 is disposed between the first transistor distribution sub-layer 21 and the second transistor distribution sub-layer 22.

The first transistor distribution sub-layer 21 includes the first active film layer 110 and the first gate film layer 111. The driving transistor T1 and the writing transistor T2 of the pixel driving circuit 20 are arranged in the first transistor distribution sub-layer 21. Since the material of the first active film layer 110 is the low-temperature polysilicon, the driving transistor T1 and the writing transistor T2 are low-temperature polysilicon transistors.

The second transistor distribution sub-layer 22 includes the second active film layer 113 and the second gate film layer 114. The sensing transistor T3 of the pixel driving circuit 20 is arranged in the second transistor distribution sub-layer 22. Since the second active film layer 113 may be made of any one of indium gallium zinc oxide or low-temperature polycrystalline oxide, the sensing transistor T3 is an oxide transistor.

In the embodiments, the driving transistor T1 may be a dual-gate transistor, which includes the active layer pattern T11 of the driving transistor T1, the gate pattern T12 (top gate pattern) of the driving transistor T1, and a bottom gate pattern T13 of the driving transistor T1. The active layer pattern T11 of the driving transistor T1 is arranged in the first active film layer 110, the gate pattern T12 (top gate pattern) of the driving transistor T1 is arranged in the first gate film layer 111, and the bottom gate pattern T13 of the driving transistor T1 is arranged in the light-shielding layer 117. The active layer pattern T11 of the driving transistor T1 includes a source region T11c of the driving transistor T1, a drain region T11b of the driving transistor T1, and a channel region T11a of the driving transistor T1 located between the source region T11c and the drain region T11b of the driving transistor T1.

In the embodiments, the writing transistor T2 may be a top-gate transistor, which includes the active layer pattern T21 and the gate pattern T22 of the writing transistor T2. The active layer pattern T21 of the writing transistor T2 is arranged in the first active film layer 110, and the gate pattern T22 of the writing transistor T2 is arranged in the first gate film layer 111. The active layer pattern T21 of the writing transistor T2 includes a source region T21c of the writing transistor T2, a drain region T21b of the writing transistor T2, and a channel region T21a of the writing transistor T2 located between the source region T21c and the drain region T21b of the writing transistor T2.

In the embodiments, the sensing transistor T3 may be a dual-gate transistor, which includes the active layer pattern T31 of the sensing transistor T3, the gate pattern T32 (top gate pattern) of the sensing transistor T3, and a bottom gate pattern T33 of the sensing transistor T3. The active layer pattern T31 of the sensing transistor T3 is arranged in the second active film layer 113, the gate pattern T32 (top gate pattern) of the sensing transistor T3 is arranged in the second gate film layer 114, and the bottom gate pattern T33 of the sensing transistor T3 is arranged in the first gate film layer 111. The active layer pattern T31 of the sensing transistor T3 includes a source region T31c of the sensing transistor T3, a drain region T31b of the sensing transistor T3, and a channel region T31a of the sensing transistor T3 located between the source region T31c and the drain region T31b of the sensing transistor T3.

The first source-drain metal layer 109 includes data signal lines 1091.

The fourth gate film layer 112 includes the first source transfer pattern 1121 of the driving transistor T1, the first drain transfer pattern 1122 of the writing transistor T2, and the source transfer pattern 1123 of the writing transistor T2. It should be noted that, in the embodiments, the fourth gate film layer 112 not only serves as the first transfer gate film layer, but also as the second transfer gate film layer and the third transfer gate film layer.

Compared with the situation where source transfer patterns/drain transfer patterns of transistors are all arranged in the second source-drain metal layer 115′ in an embodiment shown in FIG. 5, in the embodiments, the fourth gate film layer 112 simultaneously serves as the first transfer gate film layer, the second transfer gate film layer and the third transfer gate film layer, in which the first source transfer pattern 1121 of the driving transistor T1, the first drain transfer pattern 1122 of the writing transistor T2 and the source transfer pattern 1123 of the writing transistor T2 are arranged. Thus, the wiring difficulty of other film layers (the second source-drain metal layer 115) in the array substrate 10 may be reduced, which is conducive to further improving the PPI (pixels per inch, pixel density) of the display panel 100.

The second source-drain metal layer 115 includes first voltage signal lines 1151, anode transfer patterns 1152, and first sensing signal lines 1153.

The active layer pattern T11 of the driving transistor T1 is connected to a first voltage signal line 1151 through a via hole. Specifically, the drain region T11b of the active layer pattern T11 of the driving transistor T1 is connected to the first voltage signal line 1151 through the via hole. The active layer pattern T11 of the driving transistor T1 is connected to an anode transfer pattern 1152 through a via hole and the first source transfer pattern 1121 of the driving transistor T1. Specifically, the source region T11c of the active layer pattern T11 of the driving transistor T1 is connected to the anode transfer pattern 1152 through the via hole and the first source transfer pattern 1121 of the driving transistor T1.

The active layer pattern T21 of the writing transistor T2 is electrically connected to a data signal line 1091 through a via hole and the first drain transfer pattern 1122 of the writing transistor T2. Specifically, the drain region T21b of the active layer pattern T21 of the writing transistor T2 is electrically connected to the data signal line 1091 through the via hole and the first drain transfer pattern 1122 of the writing transistor T2. The active layer pattern T21 of the writing transistor T2 is electrically connected to the gate pattern T12 of the driving transistor T1 through a via hole and the source transfer pattern 1123 of the writing transistor T2. Specifically, the source region T21c of the active layer pattern T21 of the writing transistor T2 is electrically connected to the gate pattern T12 of the driving transistor T1 through the via hole and the source transfer pattern 1123 of the writing transistor T2.

The active layer pattern T31 of the sensing transistor T3 is electrically connected to a first sensing signal line 1153 through a via hole. Specifically, the drain region T31b of the active layer pattern T31 of the sensing transistor T3 is electrically connected to the first sensing signal line 1153 through the via hole. The active layer pattern T31 of the sensing transistor T3 is electrically connected to the anode transfer pattern 1152 through a via hole. Specifically, the source region T31c of the active layer pattern T31 of the sensing transistor T3 is electrically connected to the anode transfer pattern 1152 through the via hole.

The differences between the embodiments shown in FIGS. 7 and 8 and the embodiments shown in FIG. 6 are as follows.

The array substrate 10 in the embodiments shown in FIGS. 7 and 8 further includes the light-shielding layer 117 and the third buffer layer 116. In the embodiments shown in FIG. 7, the light-shielding layer 117 and the third buffer layer 116 are arranged between the first buffer layer 102 and the first source-drain metal layer 109; and in the embodiments shown in FIG. 8, the third buffer layer 116 and the light-shielding layer 117 are arranged between the first source-drain metal layer 109 and the first gate insulating layer 103.

The driving transistor T1 and the sensing transistor T3 in the embodiments shown in FIGS. 7 and 8 are both dual-gate transistors. The bottom gate pattern T13 of the driving transistor T1 is arranged in the light-shielding layer 117, and the bottom gate pattern T33 of the sensing transistor T3 is arranged in the first gate film layer 111.

Next, embodiments in which the transistor distribution layer 2 includes three transistor distribution sub-layers is described.

An array substrate 10 shown in FIGS. 9A to 9P will be introduced below. In some embodiments, as shown in FIGS. 9A to 9P, FIG. 9A is a structural diagram of the array substrate 10 in accordance with some embodiments of the present disclosure, FIGS. 9B to 9N are plan views showing structures of various film layers of the array substrate 10 in FIG. 9A, FIG. 9O is a structural diagram of stacked film layers of the array substrate 10 shown in FIG. 9A, and FIG. 9P is a structural diagram of a stacked film layer layout of the array substrate 10 shown in FIG. 9A. The array substrate 10 includes the base substrate 101, a first buffer layer 102, a first source-drain metal layer 109, a first gate insulating layer 103, a first active film layer 110, a second gate insulating layer 104, a first gate film layer 111, a third gate insulating layer 105, a fourth gate film layer 112, a second buffer layer 106, a second active film layer 113, a fourth gate insulating layer 107, a second gate film layer 114, a fourth buffer layer 121, a third active film layer 119, a fifth gate insulating layer 118, a third gate film layer 120, an interlayer dielectric layer 108 and a second source-drain metal layer 115 that are stacked in sequence.

A material of the first active film layer 110 may be low-temperature polysilicon. A material of the second active film layer 113 may be any one of indium gallium zinc oxide or low-temperature polycrystalline oxide. For example, the second active film layer 113 is made of IGZO (indium gallium zinc oxide) or IGZTO (indium gallium zinc tin oxide). A material of the third active film layer 119 may also be any one of indium gallium zinc oxide or low-temperature polycrystalline oxide. For example, the third active film layer 119 is made of IGZO (indium gallium zinc oxide) or IGZTO (indium gallium zinc tin oxide). The material of the first active film layer 110 is the low-temperature polysilicon, and the corresponding driving transistor T1 is a low-temperature polysilicon transistor. The materials of the second active film layer 113 and the third active film layer 119 are both any one of the indium gallium zinc oxide or low-temperature polycrystalline oxide, and the corresponding writing transistor T2 and sensing transistor T3 are oxide transistors. Low-temperature polysilicon transistors have the advantages of high mobility and fast charging, and oxide transistors have the advantages of low leakage current. Low-temperature polysilicon transistors and oxide transistors are integrated into the array substrate 10 to form a low-temperature polycrystalline oxide (LTPO) array substrate. By utilizing the advantages of the low-temperature polysilicon transistors and the oxide transistors, the refresh frequency of the array substrate 10 may be switched to achieve low-frequency driving, which is beneficial to reducing power consumption and improving display quality. For example, the first active film layer 110 may be obtained by using an excimer laser annealing process, and the second active film layer 113 and the third active film layer 119 may be obtained by using a PVD (physical vapor deposition) process.

For example, the fourth buffer layer 121 may be manufactured by PECVD (plasma enhanced chemical vapor deposition), and the material thereof may be silicon nitride, silicon oxide or silicon oxynitride, which has the function of blocking moisture and gas.

For example, the fifth gate insulating layer 118 is made of silicon nitride, silicon oxide or silicon oxynitride, and obtained by depositing using a PECVD process.

For example, the third gate film layer 120 may be obtained by depositing a metal material such as MO/Ti/AI/Cu (molybdenum/titanium/aluminum/copper) by a PVD process.

The materials and manufacturing processes of the first buffer layer 102, the second buffer layer 106, the first gate insulating layer 103, the second gate insulating layer 104, the third gate insulating layer 105, the fourth gate insulating layer 107, the first gate film layer 111, the fourth gate film layer 112, the second gate film layer 114 and the interlayer dielectric layer 108 are basically the same as those in the embodiments shown in FIG. 6, which are not repeated here.

With continued reference to FIG. 9A, the transistor distribution layer 2 includes the first transistor distribution sub-layer 21, the fourth gate film layer 112, the second transistor distribution sub-layer 22, and a third transistor distribution sub-layer 23 that are stacked in sequence. The first transistor distribution sub-layer 21 is closer to the base substrate 101 than the third transistor distribution sub-layer 23. That is, a distance between the first transistor distribution sub-layer 21 and the base substrate 101 is smaller than a distance between the third transistor distribution sub-layer 23 and the base substrate 101. The fourth gate film layer 112 is arranged between the first transistor distribution sub-layer 21 and the second transistor distribution sub-layer 22.

The first transistor distribution sub-layer 21 includes the first active film layer 110 and the first gate film layer 111. The driving transistor T1 of the pixel driving circuit 20 is arranged in the first transistor distribution sub-layer 21. Since the material of the first active film layer 110 is the low-temperature polysilicon, the driving transistor T1 is a low-temperature polysilicon transistor.

The second transistor distribution sub-layer 22 includes the second active film layer 113 and the second gate film layer 114. The writing transistor T2 of the pixel driving circuit 20 is arranged in the second transistor distribution sub-layer 22. Since the second active film layer 113 may be made of any one of indium gallium zinc oxide or low-temperature polycrystalline oxide, the writing transistor T2 is an oxide transistor.

The third transistor distribution sub-layer 23 includes the third active film layer 119 and the third gate film layer 120. The sensing transistor T3 of the pixel driving circuit 20 is arranged in the third transistor distribution sub-layer 23. Since the third active film layer 119 may be made of any one of indium gallium zinc oxide or low-temperature polycrystalline oxide, the sensing transistor T3 is an oxide transistor.

In the embodiments, the driving transistor T1 may be a top-gate transistor, which includes the active layer pattern T11 and the gate pattern T12 of the driving transistor T1. As shown in FIG. 9C, the active layer pattern T11 of the driving transistor T1 is arranged in the first active film layer 110, and the active layer pattern T11 of the driving transistor T1 includes a source region T11c of the driving transistor T1, a drain region T11b of the driving transistor T1, and a channel region T11a of the driving transistor T1 located between the source region T11c and the drain region T11b of the driving transistor T1. As shown in FIG. 9D, the gate pattern T12 of the driving transistor T1 is arranged in the first gate film layer 111.

In the embodiments, the writing transistor T2 may be a top-gate transistor, which includes the active layer pattern T21 and the gate pattern T22 of the writing transistor T2. As shown in FIG. 9G, the active layer pattern T21 of the writing transistor T2 is arranged in the second active film layer 113, and the active layer pattern T21 of the writing transistor T2 includes a source region T21c of the writing transistor T2, a drain region T21b of the writing transistor T2, and a channel region T21a of the writing transistor T2 located between the source region T21c and the drain region T21b of the writing transistor T2. The gate pattern T22 of the writing transistor T2 is arranged in the second gate film layer 114.

In the embodiments, the sensing transistor T3 may be a top-gate transistor, which includes the active layer pattern T31 and the gate pattern T32 of the sensing transistor T3. As shown in FIG. 9J, the active layer pattern T31 of the sensing transistor T3 is arranged in the third active film layer 119, and the active layer pattern T31 of the sensing transistor T3 includes a source region T31c of the sensing transistor T3, a drain region T31b of the sensing transistor T3, and a channel region T31a of the sensing transistor T3 located between the source region T31c and the drain region T31b of the sensing transistor T3. As shown in FIG. 9K, the gate pattern T32 of the sensing transistor T3 is arranged in the third gate film layer 120.

As shown in FIGS. 9B and 9O, the first source-drain metal layer 109 includes data signal lines 1091.

As shown in FIGS. 9F and 9O, the fourth gate film layer 112 includes a first source transfer pattern 1121 of the driving transistor T1, a drain transfer pattern 1124 of the driving transistor T1, and a first drain transfer pattern 1122 of the writing transistor T2. It should be noted that, in the embodiments, the fourth gate film layer 112 not only serves as the third transfer gate film layer, but also as the first transfer gate film layer.

As shown in FIGS. 9I and 9O, the second gate film layer 114 includes a second source transfer pattern 1141 of the driving transistor T1, a source transfer pattern 1123 of the writing transistor T2, and a second drain transfer pattern 1142 of the writing transistor T2. It should be noted that, in the embodiments, the second gate film layer 114 not only serves as the third transfer gate film layer, but also as the second transfer gate film layer and the first transfer gate film layer.

Compared with the situation where source transfer patterns/drain transfer patterns of transistors are all arranged in the second source-drain metal layer 115′ in an embodiment shown in FIG. 5, in the embodiments, the second gate film layer 114 in the second transistor distribution sub-layer 22 simultaneously serves as the third transfer gate film layer, the second transfer gate film layer and the first transfer gate film layer, in which the second source transfer pattern 1141 of the driving transistor T1, the source transfer pattern 1123 of the writing transistor T2, and the second drain transfer pattern 1142 of the writing transistor T2 are arranged, and the fourth gate film layer 112 simultaneously serves as the third transfer gate film layer and the first transfer gate film layer, in which the first source transfer pattern 1121 of the driving transistor T1, the drain transfer pattern 1124 of the driving transistor T1, and the first drain transfer pattern 1122 of the writing transistor T2 are arranged. Thus, the wiring difficulty of other film layers (the second source-drain metal layer 115) in the array substrate 10 may be reduced, which is conducive to further improving the PPI (pixels per inch, pixel density) of the display panel 100.

As shown in FIGS. 9M and 9O, the second source-drain metal layer 115 includes first voltage signal lines 1151, anode transfer patterns 1152, and first sensing signal lines 1153.

The active layer pattern T11 of the driving transistor T1 is connected to a first voltage signal line 1151 through a via hole and the drain transfer pattern 1124 of the driving transistor T1. Specifically, the drain region T11b of the active layer pattern T11 of the driving transistor T1 is connected to the first voltage signal line 1151 through the via hole and the drain transfer pattern 1124. The active layer pattern T11 of the driving transistor T1 is connected to an anode transfer pattern 1152 through a via hole, the first source transfer pattern 1121 of the driving transistor T1, and the second source transfer pattern 1141 of the driving transistor T1. Specifically, the source region T11c of the active layer pattern T11 of the driving transistor T1 is connected to the anode transfer pattern 1152 through the via hole, the first source transfer pattern 1121 of the driving transistor T1, and the second source transfer pattern 1141 of the driving transistor T1.

The active layer pattern T21 of the writing transistor T2 is electrically connected to a data signal line 1091 through a via hole, the first drain transfer pattern 1122 of the writing transistor T2, and the second drain transfer pattern 1142 of the writing transistor T2. Specifically, the drain region T21b of the active layer pattern T21 of the writing transistor T2 is electrically connected to the data signal line 1091 through the via hole, the first drain transfer pattern 1122 of the writing transistor T2, and the second drain transfer pattern 1142 of the writing transistor T2. The active layer pattern T21 of the writing transistor T2 is electrically connected to the gate pattern T12 of the driving transistor T1 through a via hole and the source transfer pattern 1123 of the writing transistor T2. Specifically, the source region T21c of the active layer pattern T21 of the writing transistor T2 is electrically connected to the gate pattern T12 of the driving transistor T1 through the via hole and the source transfer pattern 1123 of the writing transistor T2.

The active layer pattern T31 of the sensing transistor T3 is electrically connected to a first sensing signal line 1153 through a via hole. Specifically, the drain region T31b of the active layer pattern T31 of the sensing transistor T3 is electrically connected to the first sensing signal line 1153 through the via hole. The active layer pattern T31 of the sensing transistor T3 is electrically connected to the anode transfer pattern 1152 through a via hole. Specifically, the source region T31c of the active layer pattern T31 of the sensing transistor T3 is electrically connected to the anode transfer pattern 1152 through the via hole.

For example, with continued reference to FIG. 9A, in the Z direction, there is an overlapping region CC between the active layer pattern T21 of the writing transistor T2 arranged in the second transistor distribution sub-layer 22 and the active layer pattern T31 of the sensing transistor T3 arranged in the third transistor distribution sub-layer 23. By setting the overlapping region CC, the area of the sub-pixel region A1 may be further reduced, which is beneficial to further improving the PPI of the array substrate 10.

In some embodiments, as shown in FIG. 9O, at least three sub-pixel regions A1 constitute one pixel unit region P.

The description “at least three sub-pixel regions A1 constitute one pixel unit region P” means that each pixel unit region P may include three, four or more sub-pixel regions A1, and the multiple sub-pixel regions A1 included in each pixel unit region P may be a row, a column or a group of sub-pixel regions A1. The sub-pixel regions A1 in a single group may be a plurality of sub-pixel regions A1 adjacent to each other, and the adjacent plurality of sub-pixel regions A1 are arranged in a row, a column, an L-shape, a rectangle or a diamond, etc. Moreover, light-emitting areas of the multiple sub-pixel regions A1 included in each pixel unit region P may be the same or may not be exactly the same. The above is only exemplary description and is not used to limit the present disclosure. Adaptive design can be performed according to actual needs.

In some examples, the multiple sub-pixel regions A1 emit light of the same color, and the array substrate 10 may further include a color filter layer disposed on a light-exit side of the multiple sub-pixel regions A1.

For example, the multiple sub-pixel regions A1 all emit white light, red light, green light, blue light or light of other color. In this case, after passing through the color filter layer, the corresponding color light emitted by the sub-pixel region A1 remains the same color light, or is converted into other color light for exiting. Therefore, in a case where the multiple sub-pixel regions A1 emit the same color light, the array substrate 10 can achieve multi-color exit light.

In some other examples, the multiple sub-pixel regions A1 emit light of different colors. For example, the multiple sub-pixel regions A1 include a red sub-pixel region A1 that emits red light, a green sub-pixel region A1 that emits green light, and a blue sub-pixel region A1 that emits blue light. Therefore, the array substrate 10 can achieve multi-color exit light.

With continued reference to FIG. 9O, and in combination with FIGS. 9A to 9N, the array substrate 10 further includes second sensing signal lines 1125 disposed in the fourth gate film layer 112, and a second sensing signal line 1125 is connected to the first sensing signal line 1153 disposed in the second source-drain metal layer 115 through a via hole.

In some embodiments, as shown in FIG. 9P, and in combination with FIGS. 9A to 9O, by taking an arrangement of four pixel unit regions P in FIG. 9P as an example, the four pixel unit regions P are arranged in a 2*2 arrangement, and two adjacent unit regions P are symmetrically arranged with each other. For example, the four pixel unit regions P have a first symmetry axis M extending along a first direction X and a second symmetry axis N extending along a second direction Y, the four pixel unit regions P are symmetrically arranged along the first symmetry axis M and symmetrically arranged along the second symmetry axis N. In this way, a plurality of pixel unit regions P may be closely arranged, and the spacing between the pixel unit regions P may be reduced, which is beneficial to improving the PPI of the array substrate 10.

The second sensing signal line 1125 extends in the second direction Y, and in the first direction X, pixel unit regions P on both sides of the second sensing signal line 1125 may share the same second sensing signal line 1125, which may reduce the number of second sensing signal lines 1125 in the array substrate 10. Therefore, there is more space in the array substrate 10 for arranging pixel unit regions P, which is beneficial to further improving the PPI of the array substrate 10.

It should be noted that FIG. 9P only illustrates the arrangement of the pixel unit regions P by taking the array substrate 10 shown in FIG. 9A as an example. The arrangement of the pixel unit regions P is also applicable to the array substrate 10 in other embodiments of the present disclosure, which will not be repeated here.

An array substrate 10 shown in FIG. 10 will be introduced below. In some embodiments, as shown in FIG. 10, FIG. 10 is a structural diagram of the array substrate 10, in accordance with some embodiments of the present disclosure. The array substrate 10 includes the base substrate 101, a first buffer layer 102, a light-shielding layer 117, a third buffer layer 116, a first source-drain metal layer 109, a first gate insulating layer 103, a first active film layer 110, a second gate insulating layer 104, a first gate film layer 111, a third gate insulating layer 105, a fourth gate film layer 112, a second buffer layer 106, a second active film layer 113, a fourth gate insulating layer 107, a second gate film layer 114, a fourth buffer layer 121, a third active film layer 119, a fifth gate insulating layer 118, a third gate film layer 120, an interlayer dielectric layer 108 and a second source-drain metal layer 115 that are stacked in sequence.

It should be noted that, the embodiments are illustrated by taking an example where the light-shielding layer 117 is located on a side of the first source-drain metal layer 109 proximate to the base substrate 101 (that is, the light-shielding layer 117 is located between the first source-drain metal layer 109 and the base substrate 101). However, the positional relationship between the light-shielding layer 117 and the first source-drain metal layer 109 is not limited to this. For example, the positions of the light-shielding layer 117 and the first source-drain metal layer 109 can be interchangeable, and the light-shielding layer 117 is located on a side of the first source-drain metal layer 109 away from the base substrate 101 (that is, the first source-drain metal layer 109 is located between the light-shielding layer 117 and the base substrate 101).

The light-shielding layer 117 can shield light directed to the array substrate 10 from a side of the base substrate 101 away from the light-shielding layer 117. For example, a material of the light-shielding layer 117 may be amorphous silicon.

For example, the third buffer layer 116 may be manufactured by PECVD (plasma enhanced chemical vapor deposition), and the material thereof may be silicon nitride, silicon oxide or silicon oxynitride, which has the function of blocking moisture and gas.

The materials and manufacturing processes of the first active film layer 110, the second active film layer 113, the third active film layer 119, the first buffer layer 102, the second buffer layer 106, the fourth buffer layer 121, the first gate insulating layer 103, the second gate insulating layer 104, the third gate insulating layer 105, the fourth gate insulating layer 107, the fifth gate insulating layer 118, the first gate film layer 111, the fourth gate film layer 112, the second gate film layer 114, the third gate film layer 120 and the interlayer dielectric layer 108 are basically the same as those in the embodiments shown in FIG. 9A, which are not repeated here.

With continued reference to FIG. 10, the transistor distribution layer 2 includes the first transistor distribution sub-layer 21, the fourth gate film layer 112, the second transistor distribution sub-layer 22, and the third transistor distribution sub-layer 23 that are stacked in sequence. The first transistor distribution sub-layer 21 is closer to the base substrate 101 than the third transistor distribution sub-layer 23. That is, a distance between the first transistor distribution sub-layer 21 and the base substrate 101 is smaller than a distance between the third transistor distribution sub-layer 23 and the base substrate 101. The fourth gate film layer 112 is arranged between the first transistor distribution sub-layer 21 and the second transistor distribution sub-layer 22.

The first transistor distribution sub-layer 21 includes the first active film layer 110 and the first gate film layer 111. The driving transistor T1 of the pixel driving circuit 20 is arranged in the first transistor distribution sub-layer 21. Since the material of the first active film layer 110 is the low-temperature polysilicon, the driving transistor T1 is a low-temperature polysilicon transistor.

The second transistor distribution sub-layer 22 includes the second active film layer 113 and the second gate film layer 114. The writing transistor T2 of the pixel driving circuit 20 is arranged in the second transistor distribution sub-layer 22. Since the second active film layer 113 may be made of any one of indium gallium zinc oxide or low-temperature polycrystalline oxide, the writing transistor T2 is an oxide transistor.

The third transistor distribution sub-layer 23 includes the third active film layer 119 and the third gate film layer 120. The sensing transistor T3 of the pixel driving circuit 20 is arranged in the third transistor distribution sub-layer 23. Since the third active film layer 119 may be made of any one of indium gallium zinc oxide or low-temperature polycrystalline oxide, the sensing transistor T3 is an oxide transistor.

In the embodiments, the driving transistor T1 may be a dual-gate transistor, which includes the active layer pattern T11 of the driving transistor T1, the gate pattern T12 (top gate pattern) of the driving transistor T1, and a bottom gate pattern T13 of the driving transistor T1. The active layer pattern T11 of the driving transistor T1 is arranged in the first active film layer 110, the gate pattern T12 (top gate pattern) of the driving transistor is arranged in the first gate film layer 111, and the bottom gate pattern T13 of the driving transistor T1 is arranged in the light-shielding layer 117. The active layer pattern T11 of the driving transistor T1 includes a source region T11c of the driving transistor T1, a drain region T11b of the driving transistor T1, and a channel region T11a of the driving transistor T1 located between the source region T11c and the drain region T11b of the driving transistor T1.

In the embodiments, the writing transistor T2 may be a top-gate transistor, which includes the active layer pattern T21 and the gate pattern T22 of the writing transistor T2. The active layer pattern T21 of the writing transistor T2 is arranged in the second active film layer 113, and the gate pattern T22 of the writing transistor T2 is arranged in the second gate film layer 114. The active layer pattern T21 of the writing transistor T2 includes a source region T21c of the writing transistor T2, a drain region T21b of the writing transistor T2, and a channel region T21a of the writing transistor T2 located between the source region T21c and the drain region T21b of the writing transistor T2.

In the embodiments, the sensing transistor T3 may be a top-gate transistor, which includes the active layer pattern T31 and the gate pattern T32 of the sensing transistor T3. The active layer pattern T31 of the sensing transistor T3 is arranged in the third active film layer 119, and the gate pattern T32 of the sensing transistor T3 is arranged in the third gate film layer 120. The active layer pattern T31 of the sensing transistor T3 includes a source region T31c of the sensing transistor T3, a drain region T31b of the sensing transistor T3, and a channel region T31a of the sensing transistor T3 located between the source region T31c and the drain region T31b of the sensing transistor T3.

The first source-drain metal layer 109 includes data signal lines 1091.

The fourth gate film layer 112 includes a first source transfer pattern 1121 of the driving transistor T1, a drain transfer pattern 1124 of the driving transistor T1, and a first drain transfer pattern 1122 of the writing transistor T2. It should be noted that, in the embodiments, the fourth gate film layer 112 not only serves as the third transfer gate film layer, but also as the first transfer gate film layer.

The second gate film layer 114 includes a second source transfer pattern 1141 of the driving transistor T1, a source transfer pattern 1123 of the writing transistor T2, and a second drain transfer pattern 1142 of the writing transistor T2. It should be noted that, in the embodiments, the second gate film layer 114 not only serves as the third transfer gate film layer, but also as the second transfer gate film layer and the first transfer gate film layer.

Compared with the situation where source transfer patterns/drain transfer patterns of transistors are all arranged in the second source-drain metal layer 115′ in an embodiment shown in FIG. 5, in the embodiments, the second gate film layer 114 in the second transistor distribution sub-layer 22 simultaneously serves as the third transfer gate film layer, the second transfer gate film layer and the first transfer gate film layer, in which the second source transfer pattern 1141 of the driving transistor T1, the source transfer pattern 1123 of the writing transistor T2, and the second drain transfer pattern 1142 of the writing transistor T2 are arranged, and the fourth gate film layer 112 simultaneously serves as the third transfer gate film layer and the first transfer gate film layer, in which the first source transfer pattern 1121 of the driving transistor T1, the drain transfer pattern 1124 of the driving transistor T1, and the first drain transfer pattern 1122 of the writing transistor T2 are arranged. Thus, the wiring difficulty of other film layers (the second source-drain metal layer 115) in the array substrate 10 may be reduced, which is conducive to further improving the PPI (pixels per inch, pixel density) of the display panel 100.

The second source-drain metal layer 115 includes first voltage signal lines 1151, anode transfer patterns 1152, and first sensing signal lines 1153.

The active layer pattern T11 of the driving transistor T1 is connected to a first voltage signal line 1151 through a via hole and the drain transfer pattern 1124 of the driving transistor T1. Specifically, the drain region T11b of the active layer pattern T11 of the driving transistor T1 is connected to the first voltage signal line 1151 through the via hole and the drain transfer pattern 1124. The active layer pattern T11 of the driving transistor T1 is connected to an anode transfer pattern 1152 through a via hole, the first source transfer pattern 1121 of the driving transistor T1, and the second source transfer pattern 1141 of the driving transistor T1. Specifically, the source region T11c of the active layer pattern T11 of the driving transistor T1 is connected to the anode transfer pattern 1152 through the via hole, the first source transfer pattern 1121 of the driving transistor T1, and the second source transfer pattern 1141 of the driving transistor T1.

The active layer pattern T21 of the writing transistor T2 is electrically connected to a data signal line 1091 through a via hole, the first drain transfer pattern 1122 of the writing transistor T2, and the second drain transfer pattern 1142 of the writing transistor T2. Specifically, the drain region T21b of the active layer pattern T21 of the writing transistor T2 is electrically connected to the data signal line 1091 through the via hole, the first drain transfer pattern 1122 of the writing transistor T2, and the second drain transfer pattern 1142 of the writing transistor T2. The active layer pattern T21 of the writing transistor T2 is electrically connected to the gate pattern T12 of the driving transistor T1 through a via hole and the source transfer pattern 1123 of the writing transistor T2. Specifically, the source region T21c of the active layer pattern T21 of the writing transistor T2 is electrically connected to the gate pattern T12 of the driving transistor T1 through the via hole and the source transfer pattern 1123 of the writing transistor T2.

The active layer pattern T31 of the sensing transistor T3 is electrically connected to a first sensing signal line 1153 through a via hole. Specifically, the drain region T31b of the active layer pattern T31 of the sensing transistor T3 is electrically connected to the first sensing signal line 1153 through the via hole. The active layer pattern T31 of the sensing transistor T3 is electrically connected to the anode transfer pattern 1152 through a via hole. Specifically, the source region T31c of the active layer pattern T31 of the sensing transistor T3 is electrically connected to the anode transfer pattern 1152 through the via hole.

For example, in the Z direction, there is an overlapping region CC between the active layer pattern T21 of the writing transistor T2 arranged in the second transistor distribution sub-layer 22 and the active layer pattern T31 of the sensing transistor T3 arranged in the third transistor distribution sub-layer 23. By setting the overlapping region CC, the area of the sub-pixel region A1 may be further reduced, which is beneficial to further improving the PPI of the array substrate 10.

The difference between the embodiments shown in FIG. 10 and the embodiments shown in FIG. 9A is as follows.

The array substrate 10 in the embodiments shown in FIG. 10 further includes the light-shielding layer 117 and the third buffer layer 116.

The driving transistor T1 in the embodiments shown in FIG. 10 is a dual-gate transistor. A bottom gate pattern T13 of the driving transistor T1 is arranged in the light-shielding layer 117.

An array substrate 10 shown in FIG. 11 will be introduced below. In some embodiments, as shown in FIG. 11, FIG. 11 is a structural diagram of the array substrate 10, in accordance with some embodiments of the present disclosure. The array substrate 10 includes the base substrate 101, a first buffer layer 102, a light-shielding layer 117, a third buffer layer 116, a first source-drain metal layer 109, a first gate insulating layer 103, a first active film layer 110, a second gate insulating layer 104, a first gate film layer 111, a third gate insulating layer 105, a fourth gate film layer 112, a second buffer layer 106, a second active film layer 113, a fourth gate insulating layer 107, a second gate film layer 114, a fifth gate insulating layer 118, a third active film layer 119, a second source-drain metal layer 115, a passivation layer 122 and a third source-drain metal layer 123 that are stacked in sequence.

It should be noted that, the embodiments are illustrated by taking an example where the light-shielding layer 117 is located on a side of the first source-drain metal layer 109 proximate to the base substrate 101 (that is, the light-shielding layer 117 is located between the first source-drain metal layer 109 and the base substrate 101). However, the positional relationship between the light-shielding layer 117 and the first source-drain metal layer 109 is not limited to this. For example, the positions of the light-shielding layer 117 and the first source-drain metal layer 109 can be interchangeable, and the light-shielding layer 117 is located on a side of the first source-drain metal layer 109 away from the base substrate 101 (that is, the first source-drain metal layer 109 is located between the light-shielding layer 117 and the base substrate 101).

The light-shielding layer 117 can shield light directed to the array substrate 10 from a side of the base substrate 101 away from the light-shielding layer 117. For example, a material of the light-shielding layer 117 may be amorphous silicon.

For example, the third buffer layer 116 may be manufactured by PECVD (plasma enhanced chemical vapor deposition), and the material thereof may be silicon nitride, silicon oxide or silicon oxynitride, which has the function of blocking moisture and gas.

A material of the passivation layer 122 may be silicon nitride, silicon oxide, or silicon oxynitride.

The third source-drain metal layer 123 may be obtained by depositing a metal material such as MO/Ti/AI/Cu (molybdenum/titanium/aluminum/copper) using a PVD process.

The materials and manufacturing processes of the first active film layer 110, the second active film layer 113, the third active film layer 119, the first buffer layer 102, the second buffer layer 106, the first gate insulating layer 103, the second gate insulating layer 104, the third gate insulating layer 105, the fourth gate insulating layer 107, the fifth gate insulating layer 118, the first gate film layer 111, the fourth gate film layer 112, and the second gate film layer 114 are basically the same as those in the embodiments shown in FIG. 9A, which are not repeated here.

With continued reference to FIG. 11, the transistor distribution layer 2 includes the first transistor distribution sub-layer 21, the fourth gate film layer 112, the second transistor distribution sub-layer 22, and the third transistor distribution sub-layer 23 that are stacked in sequence. The first transistor distribution sub-layer 21 is closer to the base substrate 101 than the third transistor distribution sub-layer 23. That is, a distance between the first transistor distribution sub-layer 21 and the base substrate 101 is smaller than a distance between the third transistor distribution sub-layer 23 and the base substrate 101. The fourth gate film layer 112 is arranged between the first transistor distribution sub-layer 21 and the second transistor distribution sub-layer 22.

The first transistor distribution sub-layer 21 includes the first active film layer 110 and the first gate film layer 111. The driving transistor T1 of the pixel driving circuit 20 is arranged in the first transistor distribution sub-layer 21. Since the material of the first active film layer 110 is the low-temperature polysilicon, the driving transistor T1 is a low-temperature polysilicon transistor.

The second transistor distribution sub-layer 22 includes the second active film layer 113 and the second gate film layer 114. The writing transistor T2 of the pixel driving circuit 20 is arranged in the second transistor distribution sub-layer 22. Since the second active film layer 113 may be made of any one of indium gallium zinc oxide or low-temperature polycrystalline oxide, the writing transistor T2 is an oxide transistor.

The third transistor distribution sub-layer 23 includes the third active film layer 119, and the sensing transistor T3 of the pixel driving circuit 20 is arranged in the third transistor distribution sub-layer 23. Since the third active film layer 119 may be made of any one of indium gallium zinc oxide or low-temperature polycrystalline oxide, the sensing transistor T3 is an oxide transistor.

In the embodiments, the driving transistor T1 may be a dual-gate transistor, which includes the active layer pattern T11 of the driving transistor T1, the gate pattern T12 (top gate pattern) of the driving transistor T1, and a bottom gate pattern T13 of the driving transistor T1. The active layer pattern T11 of the driving transistor T1 is arranged in the first active film layer 110, the gate pattern T12 (top gate pattern) of the driving transistor is arranged in the first gate film layer 111, and the bottom gate pattern T13 of the driving transistor T1 is arranged in the light-shielding layer 117. The active layer pattern T11 of the driving transistor T1 includes a source region T11c of the driving transistor T1, a drain region T11b of the driving transistor T1, and a channel region T11a of the driving transistor T1 located between the source region T11c and the drain region T11b of the driving transistor T1.

In the embodiments, the writing transistor T2 may be a top-gate transistor, which includes the active layer pattern T21 and the gate pattern T22 of the writing transistor T2. The active layer pattern T21 of the writing transistor T2 is arranged in the second active film layer 113, and the gate pattern T22 of the writing transistor T2 is arranged in the second gate film layer 114. The active layer pattern T21 of the writing transistor T2 includes a source region T21c of the writing transistor T2, a drain region T21b of the writing transistor T2, and a channel region T21a of the writing transistor T2 located between the source region T21c and the drain region T21b of the writing transistor T2.

In the embodiments, the sensing transistor T3 may be a bottom-gate transistor, which includes the active layer pattern T31 and a bottom gate pattern T33 of the sensing transistor T3. The active layer pattern T31 of the sensing transistor T3 is arranged in the third active film layer 119, and the bottom gate pattern T33 of the sensing transistor T3 is arranged in the second gate film layer 114. The active layer pattern T31 of the sensing transistor T3 includes a source region T31c of the sensing transistor T3, a drain region T31b of the sensing transistor T3, and a channel region T31a of the sensing transistor T3 located between the source region T31c and the drain region T31b of the sensing transistor T3.

The first source-drain metal layer 109 includes data signal lines 1091.

The fourth gate film layer 112 includes a first source transfer pattern 1121 of the driving transistor T1, a drain transfer pattern 1124 of the driving transistor T1, and a first drain transfer pattern 1122 of the writing transistor T2. It should be noted that, in the embodiments, the fourth gate film layer 112 not only serves as the third transfer gate film layer, but also as the first transfer gate film layer.

The second gate film layer 114 includes a source transfer pattern 1123 of the writing transistor T2 and a second drain transfer pattern 1142 of the writing transistor T2. It should be noted that, in the embodiments, the second gate film layer 114 not only serves as the second transfer gate film layer, but also as the first transfer gate film layer.

Compared with the situation where source transfer patterns/drain transfer patterns of transistors are all arranged in the second source-drain metal layer 115′ in an embodiment shown in FIG. 5, in the embodiments, the second gate film layer 114 in the second transistor distribution sub-layer 22 simultaneously serves as the second transfer gate film layer and the first transfer gate film layer, in which the source transfer pattern 1123 of the writing transistor T2 and the second drain transfer pattern 1142 of the writing transistor T2 are arranged, and the fourth gate film layer 112 simultaneously serves as the third transfer gate film layer and the first transfer gate film layer, in which the first source transfer pattern 1121 of the driving transistor T1, the drain transfer pattern 1124 of the driving transistor T1, and the first drain transfer pattern 1122 of the writing transistor T2 are arranged. Thus, the wiring difficulty of other film layers (the second source-drain metal layer 115) in the array substrate 10 may be reduced, which is conducive to further improving the PPI (pixels per inch, pixel density) of the display panel 100.

The second source-drain metal layer 115 includes first voltage signal lines 1151, anode transfer patterns 1152, and sensing patterns 1154.

The third source-drain metal layer 123 includes first sensing signal lines 1153, and a first sensing signal line 1153 is electrically connected to a sensing pattern 1154 through a via hole.

The active layer pattern T11 of the driving transistor T1 is connected to a first voltage signal line 1151 through a via hole and the drain transfer pattern 1124 of the driving transistor T1. Specifically, the drain region T11b of the active layer pattern T11 of the driving transistor T1 is connected to the first voltage signal line 1151 through the via hole and the drain transfer pattern 1124. The active layer pattern T11 of the driving transistor T1 is connected to an anode transfer pattern 1152 through a via hole and the first source transfer pattern 1121 of the driving transistor T1. Specifically, the source region T11c of the active layer pattern T11 of the driving transistor T1 is connected to the anode transfer pattern 1152 through the via hole and the first source transfer pattern 1121 of the driving transistor T1.

The active layer pattern T21 of the writing transistor T2 is electrically connected to a data signal line 1091 through a via hole, the first drain transfer pattern 1122 of the writing transistor T2, and the second drain transfer pattern 1142 of the writing transistor T2. Specifically, the drain region T21b of the active layer pattern T21 of the writing transistor T2 is electrically connected to the data signal line 1091 through the via hole, the first drain transfer pattern 1122 of the writing transistor T2, and the second drain transfer pattern 1142 of the writing transistor T2. The active layer pattern T21 of the writing transistor T2 is electrically connected to the gate pattern T12 of the driving transistor T1 through a via hole and the source transfer pattern 1123 of the writing transistor T2. Specifically, the source region T21c of the active layer pattern T21 of the writing transistor T2 is electrically connected to the gate pattern T12 of the driving transistor T1 through the via hole and the source transfer pattern 1123 of the writing transistor T2.

The active layer pattern T31 of the sensing transistor T3 is electrically connected to the sensing pattern 1154. Specifically, the drain region T31b of the active layer pattern T31 of the sensing transistor T3 is electrically connected to the first sensing signal line 1153. The active layer pattern T31 of the sensing transistor T3 is electrically connected to the anode transfer pattern 1152. Specifically, the source region T31c of the active layer pattern T31 of the sensing transistor T3 is electrically connected to the anode transfer pattern 1152. The active layer pattern T31 of the sensing transistor T3 and the sensing pattern 1154 may be directly connected without a via hole for the electrical connection, and the active layer pattern T31 of the sensing transistor T3 and the anode transfer pattern 1152 may also be directly connected without a via hole for the electrical connection, which may further reduce the number of via holes on the second source-drain metal layer 115, reduce the wiring difficulty of the second source-drain metal layer 115, and further reduce the area of the sub-pixel region A1. Thus, it is beneficial to improve the PPI of the array substrate 10.

The difference between the embodiments shown in FIG. 11 and the embodiments shown in FIG. 9A is as follows.

The array substrate 10 in the embodiments shown in FIG. 11 does not include the fourth buffer layer 121, the third gate film layer 120 and the interlayer dielectric layer 108.

The array substrate 10 in the embodiments shown in FIG. 11 further includes the light-shielding layer 117, the third buffer layer 116, the passivation layer 122 and the third source-drain metal layer 123. The third source-drain metal layer 123 includes the first sensing signal line 1153, and the second source-drain metal layer 115 includes the sensing pattern 1154 electrically connected to the first sensing signal line 1153.

In the embodiments shown in FIG. 11, the driving transistor T1 is a dual-gate transistor, and the sensing transistor T3 is a bottom-gate transistor. The bottom gate pattern T13 of the driving transistor T1 is arranged in the light-shielding layer 117, and the bottom gate pattern T33 of the sensing transistor T3 is arranged in the second gate film layer 114.

In the embodiments shown in FIG. 11, the active layer pattern T11 of the driving transistor T1 is connected to the anode transfer pattern 1152 through a via hole and the first source transfer pattern 1121 of the driving transistor T1, the active layer pattern T31 of the sensing transistor T3 is electrically connected to the sensing pattern 1154, and the active layer pattern T31 of the sensing transistor T3 is electrically connected to the anode transfer pattern 1152.

Array substrates 10 shown in FIGS. 12 and 13 will be introduced below. In some embodiments, as shown in FIGS. 12 and 13, FIGS. 12 and 13 are structural diagrams of the array substrates 10, in accordance with some embodiments of the present disclosure. The array substrate 10 includes the base substrate 101, a first buffer layer 102, a first source-drain metal layer 109, a first gate insulating layer 103, a first active film layer 110, a second gate insulating layer 104, a first gate film layer 111, a second buffer layer 106, a second active film layer 113, a third gate insulating layer 105, a second gate film layer 114, a fourth gate insulating layer 107, a fourth gate film layer 112, a fourth buffer layer 121, a third active film layer 119, a fifth gate insulating layer 118, a third gate film layer 120, an interlayer dielectric layer 108 and a second source-drain metal layer 115 that are stacked in sequence.

Materials of the first active film layer 110, the second active film layer 113 and the third active film layer 119 may all be any one of indium gallium zinc oxide or low-temperature polycrystalline oxide. For example, the first active film layer 110, the second active film layer 113 and the third active film layer 119 are made of IGZO (indium gallium zinc oxide) or IGZTO (indium gallium zinc tin oxide).

For example, the first active film layer 110, the second active film layer 113 and the third active film layer 119 are all obtained by a PVD (physical vapor deposition) process.

The materials and manufacturing processes of the first buffer layer 102, the second buffer layer 106, the fourth buffer layer 121, the first gate insulating layer 103, the second gate insulating layer 104, the third gate insulating layer 105, the fourth gate insulating layer 107, the fifth gate insulating layer 118, the first gate film layer 111, the fourth gate film layer 112, the second gate film layer 114, the third gate film layer 120 and the interlayer dielectric layer 108 are basically the same as those in the above embodiments, which are not repeated here.

With continued reference to FIGS. 12 and 13, the transistor distribution layer 2 includes the first transistor distribution sub-layer 21, the second transistor distribution sub-layer 22, the fourth gate film layer 112 and the third transistor distribution sub-layer 23 that are stacked in sequence. The first transistor distribution sub-layer 21 is closer to the base substrate 101 than the third transistor distribution sub-layer 23. That is, a distance between the first transistor distribution sub-layer 21 and the base substrate 101 is smaller than a distance between the third transistor distribution sub-layer 23 and the base substrate 101. The fourth gate film layer 112 is arranged between the second transistor distribution sub-layer 22 and the third transistor distribution sub-layer 23.

The first transistor distribution sub-layer 21 includes the first active film layer 110 and the first gate film layer 111. The writing transistor T2 of the pixel driving circuit 20 is arranged in the first transistor distribution sub-layer 21. Since the first active film layer 110 may be made of any one of indium gallium zinc oxide or low-temperature polycrystalline oxide, the writing transistor T2 is an oxide transistor.

The second transistor distribution sub-layer 22 includes the second active film layer 113 and the second gate film layer 114. The driving transistor T1 of the pixel driving circuit 20 is arranged in the second transistor distribution sub-layer 22. Since the second active film layer 113 may be made of any one of indium gallium zinc oxide or low-temperature polycrystalline oxide, the driving transistor T1 is an oxide transistor.

The third transistor distribution sub-layer 23 includes the third active film layer 119 and the third gate film layer 120. The sensing transistor T3 of the pixel driving circuit 20 is arranged in the third transistor distribution sub-layer 23. Since the third active film layer 119 may be made of any one of indium gallium zinc oxide or low-temperature polycrystalline oxide, the sensing transistor T3 is an oxide transistor.

In the embodiments, the driving transistor T1 may be a top-gate transistor; and as shown in FIG. 12, the driving transistor T1 includes the active layer pattern T11 of the driving transistor T1 and the gate pattern T12 (top-gate pattern) of the driving transistor T1. The active layer pattern T11 of the driving transistor T1 is arranged in the second active film layer 113, and the gate pattern T12 (top gate pattern) of the driving transistor T1 is arranged in the second gate film layer 114. The active layer pattern T11 of the driving transistor T1 includes a source region T11c of the driving transistor T1, a drain region T11b of the driving transistor T1, and a channel region T11a of the driving transistor T1 located between the source region T11c and the drain region T11b of the driving transistor T1. Alternatively, in the embodiments, the driving transistor T1 may be a dual-gate transistor; and as shown in FIG. 13, the driving transistor T1 includes the active layer pattern T11 of the driving transistor T1, the gate pattern T12 (top gate pattern) of the driving transistor T1, and a bottom gate pattern T13 of the driving transistor T1. The active layer pattern T11 of the driving transistor T1 is arranged in the second active film layer 113, the gate pattern T12 (top gate pattern) of the driving transistor T1 is arranged in the second gate film layer 114, and the bottom gate pattern T13 of the driving transistor T1 is arranged in the first gate film layer 111. The active layer pattern T11 of the driving transistor T1 includes a source region T11c of the driving transistor T1, a drain region T11b of the driving transistor T1, and a channel region T11a of the driving transistor T1 located between the source region T11c and the drain region T11b of the driving transistor T1.

As shown in FIGS. 12 and 13, in the embodiments, the writing transistor T2 may be a top-gate transistor, which includes the active layer pattern T21 and the gate pattern T22 of the writing transistor T2. The active layer pattern T21 of the writing transistor T2 is arranged in the first active film layer 110, and the gate pattern T22 of the writing transistor T2 is arranged in the first gate film layer 111. The active layer pattern T21 of the writing transistor T2 includes a source region T21c of the writing transistor T2, a drain region T21b of the writing transistor T2, and a channel region T21a of the writing transistor T2 located between the source region T21c and the drain region T21b of the writing transistor T2.

In the embodiments, the sensing transistor T3 may be a top-gate transistor; and as shown in FIG. 12, the sensing transistor T3 includes the active layer pattern T31 of the sensing transistor T3 and the gate pattern T32 (top gate pattern) of the sensing transistor T3. The active layer pattern T31 of the sensing transistor T3 is arranged in the third active film layer 119, and the gate pattern T32 (top gate pattern) of the sensing transistor T3 is arranged in the third gate film layer 120. The active layer pattern T31 of the sensing transistor T3 includes a source region T31c of the sensing transistor T3, a drain region T31b of the sensing transistor T3, and a channel region T31a of the sensing transistor T3 located between the source region T31c and the drain region T31b of the sensing transistor T3. Alternatively, in the embodiments, the sensing transistor T3 may be a dual-gate transistor; and as shown in FIG. 13, the sensing transistor T3 includes the active layer pattern T31 of the sensing transistor T3, the gate pattern T32 (top gate pattern) of the sensing transistor T3, and a bottom gate pattern T33 of the sensing transistor T3. The active layer pattern T31 of the sensing transistor T3 is arranged in the third active film layer 119, the gate pattern T32 (top gate pattern) of the sensing transistor T3 is arranged in the third gate film layer 120, and the bottom gate pattern T33 of the sensing transistor T3 is arranged in the fourth gate film layer 112. The active layer pattern T31 of the sensing transistor T3 includes a source region T31c of the sensing transistor T3, a drain region T31b of the sensing transistor T3, and a channel region T31a of the sensing transistor T3 located between the source region T31c and the drain region T31b of the sensing transistor T3.

The first source-drain metal layer 109 includes data signal lines 1091.

The fourth gate film layer 112 includes a first source transfer pattern 1121 of the driving transistor T1 and a drain transfer pattern 1124 of the driving transistor T1. It should be noted that, in the embodiments, the fourth gate film layer 112 serves as the third transfer gate film layer.

The second gate film layer 114 includes a source transfer pattern 1123 of the writing transistor T2 and a second drain transfer pattern 1142 of the writing transistor T2. It should be noted that, in the embodiments, the second gate film layer 114 not only serves as the second transfer gate film layer, but also as the first transfer gate film layer.

Compared with the situation where source transfer patterns/drain transfer patterns of transistors are all arranged in the second source-drain metal layer 115′ in an embodiment shown in FIG. 5, in the embodiments, the second gate film layer 114 in the second transistor distribution sub-layer 22 simultaneously serves as the second transfer gate film layer and the first transfer gate film layer, in which the source transfer pattern 1123 of the writing transistor T2 and the second drain transfer pattern 1142 of the writing transistor T2 are arranged, and the fourth gate film layer 112 serves as the third transfer gate film layer, in which the first source transfer pattern 1121 of the driving transistor T1 and the drain transfer pattern 1124 of the driving transistor T1 are arranged. Thus, the wiring difficulty of other film layers (the second source-drain metal layer 115) in the array substrate 10 may be reduced, which is conducive to further improving the PPI (pixels per inch, pixel density) of the display panel 100.

The second source-drain metal layer 115 includes first voltage signal lines 1151, anode transfer patterns 1152, and first sensing signal lines 1153.

The active layer pattern T11 of the driving transistor T1 is connected to a first voltage signal line 1151 through a via hole and the drain transfer pattern 1124 of the driving transistor T1. Specifically, the drain region T11b of the active layer pattern T11 of the driving transistor T1 is connected to the first voltage signal line 1151 through the via hole and the drain transfer pattern 1124. The active layer pattern T11 of the driving transistor T1 is connected to an anode transfer pattern 1152 through a via hole and the first source transfer pattern 1121 of the driving transistor T1. Specifically, the source region T11c of the active layer pattern T11 of the driving transistor T1 is connected to the anode transfer pattern 1152 through the via hole and the first source transfer pattern 1121 of the driving transistor T1.

The active layer pattern T21 of the writing transistor T2 is electrically connected to a data signal line 1091 through a via hole and the second drain transfer pattern 1142 of the writing transistor T2. Specifically, the drain region T21b of the active layer pattern T21 of the writing transistor T2 is electrically connected to the data signal line 1091 through the via hole and the second drain transfer pattern 1142 of the writing transistor T2. The active layer pattern T21 of the writing transistor T2 is electrically connected to the gate pattern T12 of the driving transistor T1 through a via hole and the source transfer pattern 1123 of the writing transistor T2. Specifically, the source region T21c of the active layer pattern T21 of the writing transistor T2 is electrically connected to the gate pattern T12 of the driving transistor T1 through the via hole and the source transfer pattern 1123 of the writing transistor T2.

The active layer pattern T31 of the sensing transistor T3 is electrically connected to a first sensing signal line 1153 through a via hole. Specifically, the drain region T31b of the active layer pattern T31 of the sensing transistor T3 is electrically connected to the first sensing signal line 1153 through a via hole. The active layer pattern T31 of the sensing transistor T3 is electrically connected to the anode transfer pattern 1152 through a via hole. Specifically, the source region T31c of the active layer pattern T31 of the sensing transistor T3 is electrically connected to the anode transfer pattern 1152 through the via hole.

For example, in the Z direction, there is an overlapping region CC between the active layer pattern T21 of the writing transistor T2 arranged in the first transistor distribution sub-layer 21 and the active layer pattern T31 of the sensing transistor T3 arranged in the third transistor distribution sub-layer 23. By setting the overlapping region CC, the area of the sub-pixel region A1 may be further reduced, which is beneficial to further improving the PPI of the array substrate 10.

The difference between the embodiments shown in FIG. 12 and the embodiments shown in FIG. 9A is as follows.

In the embodiments shown in FIG. 12, the driving transistor T1 is arranged in the second transistor distribution sub-layer 22, and the writing transistor T2 is arranged in the first transistor distribution sub-layer 21.

In the embodiments shown in FIG. 12, the active layer pattern T11 of the driving transistor T1 is connected to the anode transfer pattern 1152 through a via hole and the first source transfer pattern 1121 of the driving transistor T1, and the active layer pattern T21 of the writing transistor T2 is electrically connected to the data signal line 1091 through a via hole and the second drain transfer pattern 1142 of the writing transistor T2.

The difference between the embodiments shown in FIG. 13 and the embodiments shown in FIG. 9A is as follows.

In the embodiments shown in FIG. 13, the driving transistor T1, the writing transistor T2, and the sensing transistor T3 are all oxide transistors.

The driving transistor T1 and the sensing transistor T3 in the embodiments shown in FIG. 13 are both dual-gate transistors. The bottom gate pattern T13 of the driving transistor T1 is arranged in the first gate film layer 111, and the bottom gate pattern T33 of the sensing transistor T3 is arranged in the fourth gate film layer 112.

In the embodiments shown in FIG. 13, the driving transistor T1 is arranged in the second transistor distribution sub-layer 22, and the writing transistor T2 is arranged in the first transistor distribution sub-layer 21.

In the embodiments shown in FIG. 13, the active layer pattern T11 of the driving transistor T1 is connected to the anode transfer pattern 1152 through a via hole and the first source transfer pattern 1121 of the driving transistor T1, and the active layer pattern T21 of the writing transistor T2 is electrically connected to the data signal line 1091 through a via hole and the second drain transfer pattern 1142 of the writing transistor T2.

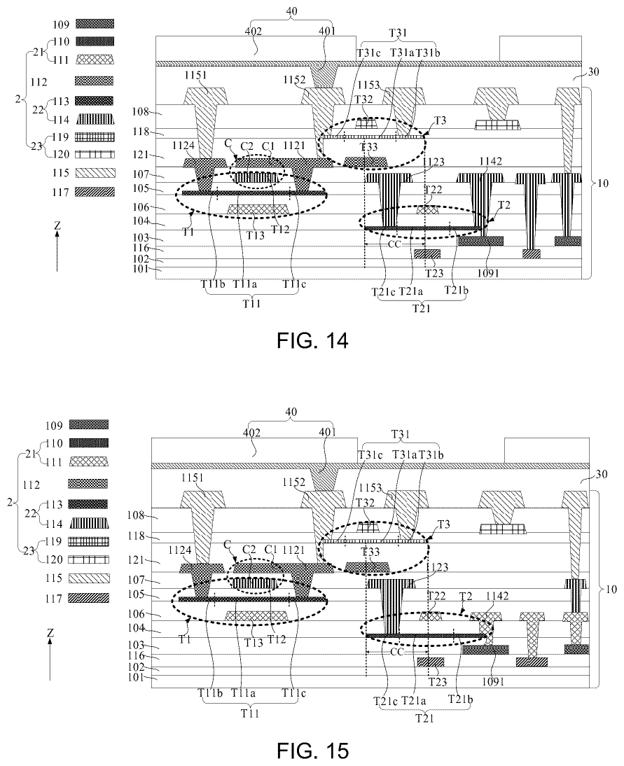

An array substrate 10 shown in FIG. 14 will be introduced below. In some embodiments, as shown in FIG. 14, FIG. 14 is a structural diagram of the array substrate 10, in accordance with some embodiments of the present disclosure. The array substrate 10 includes the base substrate 101, a first buffer layer 102, a light-shielding layer 117, a third buffer layer 116, a first source-drain metal layer 109, a first gate insulating layer 103, a first active film layer 110, a second gate insulating layer 104, a first gate film layer 111, a second buffer layer 106, a second active film layer 113, a third gate insulating layer 105, a second gate film layer 114, a fourth gate insulating layer 107, a fourth gate film layer 112, a fourth buffer layer 121, a third active film layer 119, a fifth gate insulating layer 118, a third gate film layer 120, an interlayer dielectric layer 108 and a second source-drain metal layer 115 that are stacked in sequence.

It should be noted that, the embodiments are illustrated by taking an example where the light-shielding layer 117 is located on a side of the first source-drain metal layer 109 proximate to the base substrate 101 (that is, the light-shielding layer 117 is located between the first source-drain metal layer 109 and the base substrate 101). However, the positional relationship between the light-shielding layer 117 and the first source-drain metal layer 109 is not limited to this. For example, the positions of the light-shielding layer 117 and the first source-drain metal layer 109 can be interchangeable, and the light-shielding layer 117 is located on a side of the first source-drain metal layer 109 away from the base substrate 101 (that is, the first source-drain metal layer 109 is located between the light-shielding layer 117 and the base substrate 101).

Materials of the first active film layer 110, the second active film layer 113 and the third active film layer 119 may all be any one of indium gallium zinc oxide or low-temperature polycrystalline oxide. For example, the first active film layer 110, the second active film layer 113 and the third active film layer 119 are made of IGZO (indium gallium zinc oxide) or IGZTO (indium gallium zinc tin oxide).

For example, the first active film layer 110, the second active film layer 113 and the third active film layer 119 are all obtained by a PVD (physical vapor deposition) process.

The materials and manufacturing processes of the first buffer layer 102, the second buffer layer 106, the third buffer layer 116, the fourth buffer layer 121, the first gate insulating layer 103, the second gate insulating layer 104, the third gate insulating layer 105, the fourth gate insulating layer 107, the fifth gate insulating layer 118, the first gate film layer 111, the fourth gate film layer 112, the second gate film layer 114, the third gate film layer 120, the interlayer dielectric layer 108 and the light-shielding layer 117 are basically the same as those in the above embodiments, which are not repeated here.

With continued reference to FIG. 14, the transistor distribution layer 2 includes the first transistor distribution sub-layer 21, the second transistor distribution sub-layer 22, the fourth gate film layer 112 and the third transistor distribution sub-layer 23 that are stacked in sequence. The first transistor distribution sub-layer 21 is closer to the base substrate 101 than the third transistor distribution sub-layer 23. That is, a distance between the first transistor distribution sub-layer 21 and the base substrate 101 is smaller than a distance between the third transistor distribution sub-layer 23 and the base substrate 101. The fourth gate film layer 112 is arranged between the second transistor distribution sub-layer 22 and the third transistor distribution sub-layer 23.

The first transistor distribution sub-layer 21 includes the first active film layer 110 and the first gate film layer 111. The writing transistor T2 of the pixel driving circuit 20 is arranged in the first transistor distribution sub-layer 21. Since the first active film layer 110 may be made of any one of indium gallium zinc oxide or low-temperature polycrystalline oxide, the writing transistor T2 is an oxide transistor.

The second transistor distribution sub-layer 22 includes the second active film layer 113 and the second gate film layer 114. The driving transistor T1 of the pixel driving circuit 20 is arranged in the second transistor distribution sub-layer 22. Since the second active film layer 113 may be made of any one of indium gallium zinc oxide or low-temperature polycrystalline oxide, the driving transistor T1 is an oxide transistor.

The third transistor distribution sub-layer 23 includes the third active film layer 119 and the third gate film layer 120. The sensing transistor T3 of the pixel driving circuit 20 is arranged in the third transistor distribution sub-layer 23. Since the third active film layer 119 may be made of any one of indium gallium zinc oxide or low-temperature polycrystalline oxide, the sensing transistor T3 is an oxide transistor.

In the embodiments, the driving transistor T1 may be a dual-gate transistor, which includes the active layer pattern T11 of the driving transistor T1, the gate pattern T12 (top gate pattern) of the driving transistor T1, and a bottom gate pattern T13 of the driving transistor T1. The active layer pattern T11 of the driving transistor T1 is arranged in the second active film layer 113, the gate pattern T12 (top gate pattern) of the driving transistor T1 is arranged in the second gate film layer 114, and the bottom gate pattern T13 of the driving transistor T1 is arranged in the first gate film layer 111. The active layer pattern T11 of the driving transistor T1 includes a source region T11c of the driving transistor T1, a drain region T11b of the driving transistor T1, and a channel region T11a of the driving transistor T1 located between the source region T11c and the drain region T11b of the driving transistor T1.

In the embodiments, the writing transistor T2 may be a dual-gate transistor, which includes the active layer pattern T21 of the writing transistor T2, the gate pattern T22 (top gate pattern) of the writing transistor T2, and a bottom gate pattern T23 of the writing transistor T2. The active layer pattern T21 of the writing transistor T2 is arranged in the first active film layer 110, the gate pattern T22 (top gate pattern) of the writing transistor T2 is arranged in the first gate film layer 111, and the bottom gate pattern T23 of the writing transistor T2 is arranged in the light-shielding layer 117. The active layer pattern T21 of the writing transistor T2 includes a source region T21c of the writing transistor T2, a drain region T21b of the writing transistor T2, and a channel region T21a of the writing transistor T2 located between the source region T21c and the drain region T21b of the writing transistor T2.

In the embodiments, the sensing transistor T3 may be a dual-gate transistor, which includes the active layer pattern T31 of the sensing transistor T3, the gate pattern T32 (top gate pattern) of the sensing transistor T3, and a bottom gate pattern T33 of the sensing transistor T3. The active layer pattern T31 of the sensing transistor T3 is arranged in the third active film layer 119, the gate pattern T32 (top gate pattern) of the sensing transistor T3 is arranged in the third gate film layer 120, and the bottom gate pattern T33 of the sensing transistor T3 is arranged in the fourth gate film layer 112. The active layer pattern T31 of the sensing transistor T3 includes a source region T31c of the sensing transistor T3, a drain region T31b of the sensing transistor T3, and a channel region T31a of the sensing transistor T3 located between the source region T31c and the drain region T31b of the sensing transistor T3.

The first source-drain metal layer 109 includes data signal lines 1091.

The fourth gate film layer 112 includes a first source transfer pattern 1121 of the driving transistor T1 and a drain transfer pattern 1124 of the driving transistor T1. It should be noted that, in the embodiments, the fourth gate film layer 112 serves as the third transfer gate film layer.

The second gate film layer 114 includes a source transfer pattern 1123 of the writing transistor T2 and a second drain transfer pattern 1142 of the writing transistor T2. It should be noted that, in the embodiments, the second gate film layer 114 not only serves as the second transfer gate film layer, but also as the first transfer gate film layer.

Compared with the situation where source transfer patterns/drain transfer patterns of transistors are all arranged in the second source-drain metal layer 115′ in an embodiment shown in FIG. 5, in the embodiments, the second gate film layer 114 in the second transistor distribution sub-layer 22 simultaneously serves as the second transfer gate film layer and the first transfer gate film layer, in which the source transfer pattern 1123 of the writing transistor T2 and the second drain transfer pattern 1142 of the writing transistor T2 are arranged, and the fourth gate film layer 112 serves as the third transfer gate film layer, in which the first source transfer pattern 1121 of the driving transistor T1 and the drain transfer pattern 1124 of the driving transistor T1 are arranged. Thus, the wiring difficulty of other film layers (the second source-drain metal layer 115) in the array substrate 10 may be reduced, which is conducive to further improving the PPI (pixels per inch, pixel density) of the display panel 100.

The second source-drain metal layer 115 includes first voltage signal lines 1151, anode transfer patterns 1152, and first sensing signal lines 1153.

The active layer pattern T11 of the driving transistor T1 is connected to a first voltage signal line 1151 through a via hole and the drain transfer pattern 1124 of the driving transistor T1. Specifically, the drain region T11b of the active layer pattern T11 of the driving transistor T1 is connected to the first voltage signal line 1151 through the via hole and the drain transfer pattern 1124. The active layer pattern T11 of the driving transistor T1 is connected to an anode transfer pattern 1152 through a via hole and the first source transfer pattern 1121 of the driving transistor T1. Specifically, the source region T11c of the active layer pattern T11 of the driving transistor T1 is connected to the anode transfer pattern 1152 through the via hole and the first source transfer pattern 1121 of the driving transistor T1.

The active layer pattern T21 of the writing transistor T2 is electrically connected to a data signal line 1091 through a via hole and the second drain transfer pattern 1142 of the writing transistor T2. Specifically, the drain region T21b of the active layer pattern T21 of the writing transistor T2 is electrically connected to the data signal line 1091 through the via hole and the second drain transfer pattern 1142 of the writing transistor T2. The active layer pattern T21 of the writing transistor T2 is electrically connected to the gate pattern T12 of the driving transistor T1 through a via hole and the source transfer pattern 1123 of the writing transistor T2. Specifically, the source region T21c of the active layer pattern T21 of the writing transistor T2 is electrically connected to the gate pattern T12 of the driving transistor T1 through the via hole and the source transfer pattern 1123 of the writing transistor T2.

The active layer pattern T31 of the sensing transistor T3 is electrically connected to a first sensing signal line 1153 through a via hole. Specifically, the drain region T31b of the active layer pattern T31 of the sensing transistor T3 is electrically connected to the first sensing signal line 1153 through the via hole. The active layer pattern T31 of the sensing transistor T3 is electrically connected to the anode transfer pattern 1152 through a via hole. Specifically, the source region T31c of the active layer pattern T31 of the sensing transistor T3 is electrically connected to the anode transfer pattern 1152 through the via hole.

For example, in the Z direction, there is an overlapping region CC between the active layer pattern T21 of the writing transistor T2 arranged in the first transistor distribution sub-layer 21 and the active layer pattern T31 of the sensing transistor T3 arranged in the third transistor distribution sub-layer 23. That is, in a sub-pixel region A1, the writing transistor T2 and the sensing transistor T3 have the overlapping region CC therebetween. By setting the overlapping region CC, the area of the sub-pixel region A1 may be further reduced, which is beneficial to further improving the PPI of the array substrate 10.

The difference between the embodiments shown in FIG. 14 and the embodiments shown in FIG. 9A is as follows.

In the embodiments shown in FIG. 14, the driving transistor T1, the writing transistor T2, and the sensing transistor T3 are all oxide transistors.

The driving transistor T1 and the sensing transistor T3 in the embodiments shown in FIG. 14 are both dual-gate transistors. The bottom gate pattern T13 of the driving transistor T1 is arranged in the first gate film layer 111, and the bottom gate pattern T33 of the sensing transistor T3 is arranged in the fourth gate film layer 112.

In the embodiments shown in FIG. 14, the driving transistor T1 is arranged in the second transistor distribution sub-layer 22, and the writing transistor T2 is arranged in the first transistor distribution sub-layer 21.

In the embodiments shown in FIG. 14, the active layer pattern T11 of the driving transistor T1 is connected to the anode transfer pattern 1152 through a via hole and the first source transfer pattern 1121 of the driving transistor T1, and the active layer pattern T21 of the writing transistor T2 is electrically connected to the data signal line 1091 through a via hole and the second drain transfer pattern 1142 of the writing transistor T2.

An array substrate 10 shown in FIG. 15 will be introduced below. In some embodiments, as shown in FIG. 15, FIG. 15 is a structural diagram of the array substrate 10, in accordance with some embodiments of the present disclosure. The array substrate 10 includes the base substrate 101, a first buffer layer 102, a light-shielding layer 117, a third buffer layer 116, a first source-drain metal layer 109, a first gate insulating layer 103, a first active film layer 110, a second gate insulating layer 104, a first gate film layer 111, a second buffer layer 106, a second active film layer 113, a third gate insulating layer 105, a second gate film layer 114, a fourth gate insulating layer 107, a fourth gate film layer 112, a fourth buffer layer 121, a third active film layer 119, a fifth gate insulating layer 118, a third gate film layer 120, an interlayer dielectric layer 108 and a second source-drain metal layer 115 that are stacked in sequence.

It should be noted that, the embodiments are illustrated by taking an example where the light-shielding layer 117 is located on a side of the first source-drain metal layer 109 proximate to the base substrate 101 (that is, the light-shielding layer 117 is located between the first source-drain metal layer 109 and the base substrate 101). However, the positional relationship between the light-shielding layer 117 and the first source-drain metal layer 109 is not limited to this. For example, the positions of the light-shielding layer 117 and the first source-drain metal layer 109 can be interchangeable, and the light-shielding layer 117 is located on a side of the first source-drain metal layer 109 away from the base substrate 101 (that is, the first source-drain metal layer 109 is located between the light-shielding layer 117 and the base substrate 101).

Materials of the first active film layer 110, the second active film layer 113 and the third active film layer 119 may all be any one of indium gallium zinc oxide or low-temperature polycrystalline oxide. For example, the first active film layer 110, the second active film layer 113 and the third active film layer 119 are made of IGZO (indium gallium zinc oxide) or IGZTO (indium gallium zinc tin oxide).

For example, the first active film layer 110, the second active film layer 113 and the third active film layer 119 are all obtained by a PVD (physical vapor deposition) process.

The materials and manufacturing processes of the first buffer layer 102, the second buffer layer 106, the third buffer layer 116, the fourth buffer layer 121, the first gate insulating layer 103, the second gate insulating layer 104, the third gate insulating layer 105, the fourth gate insulating layer 107, the fifth gate insulating layer 118, the first gate film layer 111, the fourth gate film layer 112, the second gate film layer 114, the third gate film layer 120, the interlayer dielectric layer 108 and the light-shielding layer 117 are basically the same as those in the above embodiments, which are not repeated here.

With continued reference to FIG. 15, the transistor distribution layer 2 includes the first transistor distribution sub-layer 21, the second transistor distribution sub-layer 22, the fourth gate film layer 112 and the third transistor distribution sub-layer 23 that are stacked in sequence. The first transistor distribution sub-layer 21 is closer to the base substrate 101 than the third transistor distribution sub-layer 23. That is, a distance between the first transistor distribution sub-layer 21 and the base substrate 101 is smaller than a distance between the third transistor distribution sub-layer 23 and the base substrate 101. The fourth gate film layer 112 is arranged between the second transistor distribution sub-layer 22 and the third transistor distribution sub-layer 23.

The first transistor distribution sub-layer 21 includes the first active film layer 110 and the first gate film layer 111. The writing transistor T2 of the pixel driving circuit 20 is arranged in the first transistor distribution sub-layer 21. Since the first active film layer 110 may be made of any one of indium gallium zinc oxide or low-temperature polycrystalline oxide, the writing transistor T2 is an oxide transistor.

The second transistor distribution sub-layer 22 includes the second active film layer 113 and the second gate film layer 114. The driving transistor T1 of the pixel driving circuit 20 is arranged in the second transistor distribution sub-layer 22. Since the second active film layer 113 may be made of any one of indium gallium zinc oxide or low-temperature polycrystalline oxide, the driving transistor T1 is an oxide transistor.

The third transistor distribution sub-layer 23 includes the third active film layer 119 and the third gate film layer 120. The sensing transistor T3 of the pixel driving circuit 20 is arranged in the third transistor distribution sub-layer 23. Since the third active film layer 119 may be made of any one of indium gallium zinc oxide or low-temperature polycrystalline oxide, the sensing transistor T3 is an oxide transistor.

In the embodiments, the driving transistor T1 may be a dual-gate transistor, which includes the active layer pattern T11 of the driving transistor T1, the gate pattern T12 (top gate pattern) of the driving transistor T1, and a bottom gate pattern T13 of the driving transistor T1. The active layer pattern T11 of the driving transistor T1 is arranged in the second active film layer 113, the gate pattern T12 (top gate pattern) of the driving transistor T1 is arranged in the second gate film layer 114, and the bottom gate pattern T13 of the driving transistor T1 is arranged in the first gate film layer 111. The active layer pattern T11 of the driving transistor T1 includes a source region T11c of the driving transistor T1, a drain region T11b of the driving transistor T1, and a channel region T11a of the driving transistor T1 located between the source region T11c and the drain region T11b of the driving transistor T1.

In the embodiments, the writing transistor T2 may be a dual-gate transistor, which includes the active layer pattern T21 of the writing transistor T2, the gate pattern T22 (top gate pattern) of the writing transistor T2, and a bottom gate pattern T23 of the writing transistor T2. The active layer pattern T21 of the writing transistor T2 is arranged in the first active film layer 110, the gate pattern T22 (top gate pattern) of the writing transistor T2 is arranged in the first gate film layer 111, and the bottom gate pattern T23 of the writing transistor T2 is arranged in the light-shielding layer 117. The active layer pattern T21 of the writing transistor T2 includes a source region T21c of the writing transistor T2, a drain region T21b of the writing transistor T2, and a channel region T21a of the writing transistor T2 located between the source region T21c and the drain region T21b of the writing transistor T2.

In the embodiments, the sensing transistor T3 may be a dual-gate transistor, which includes the active layer pattern T31 of the sensing transistor T3, the gate pattern T32 (top gate pattern) of the sensing transistor T3, and a bottom gate pattern T33 of the sensing transistor T3. The active layer pattern T31 of the sensing transistor T3 is arranged in the third active film layer 119, the gate pattern T32 (top gate pattern) of the sensing transistor T3 is arranged in the third gate film layer 120, and the bottom gate pattern T33 of the sensing transistor T3 is arranged in the fourth gate film layer 112. The active layer pattern T31 of the sensing transistor T3 includes a source region T31c of the sensing transistor T3, a drain region T31b of the sensing transistor T3, and a channel region T31a of the sensing transistor T3 located between the source region T31c and the drain region T31b of the sensing transistor T3.

The first source-drain metal layer 109 includes data signal lines 1091.

The first gate film layer 111 includes a second drain transfer pattern 1142 of the writing transistor T2. It should be noted that, in the embodiments, the first gate film layer 111 serves as the first transfer gate film layer.

The second gate film layer 114 includes a source transfer pattern 1123 of the writing transistor T2. It should be noted that, in the embodiments, the second gate film layer 114 serves as the second transfer gate film layer.

The fourth gate film layer 112 includes a first source transfer pattern 1121 of the driving transistor T1 and a drain transfer pattern 1124 of the driving transistor T1. It should be noted that, in the embodiments, the fourth gate film layer 112 serves as the third transfer gate film layer.

Compared with the situation where source transfer patterns/drain transfer patterns of transistors are all arranged in the second source-drain metal layer 115′ in an embodiment shown in FIG. 5, in the embodiments, the fourth gate film layer 112 serves as the third transfer gate film layer, in which the first source transfer pattern 1121 of the driving transistor T1 and the drain transfer pattern 1124 of the driving transistor T1 are arranged, the second gate film layer 114 in the second transistor distribution sub-layer 22 serves as the second transfer gate film layer, in which the source transfer pattern 1123 of the writing transistor T2 is arranged, and the first gate film layer 111 in the first transistor distribution sub-layer 21 serves as the first transfer gate film layer, in which the second drain transfer pattern 1142 of the writing transistor T2 is arranged. Thus, the wiring difficulty of other film layers (the second source-drain metal layer 115) in the array substrate 10 may be reduced, which is conducive to further improving the PPI (pixels per inch, pixel density) of the display panel 100.

The second source-drain metal layer 115 includes first voltage signal lines 1151, anode transfer patterns 1152, and first sensing signal lines 1153.

The active layer pattern T11 of the driving transistor T1 is connected to a first voltage signal line 1151 through a via hole and the drain transfer pattern 1124 of the driving transistor T1. Specifically, the drain region T11b of the active layer pattern T11 of the driving transistor T1 is connected to the first voltage signal line 1151 through the via hole and the drain transfer pattern 1124. The active layer pattern T11 of the driving transistor T1 is connected to an anode transfer pattern 1152 through a via hole and the first source transfer pattern 1121 of the driving transistor T1. Specifically, the source region T11c of the active layer pattern T11 of the driving transistor T1 is connected to the anode transfer pattern 1152 through the via hole and the first source transfer pattern 1121 of the driving transistor T1.

The active layer pattern T21 of the writing transistor T2 is electrically connected to a data signal line 1091 through a via hole and the second drain transfer pattern 1142 of the writing transistor T2. Specifically, the drain region T21b of the active layer pattern T21 of the writing transistor T2 is electrically connected to the data signal line 1091 through the via hole and the second drain transfer pattern 1142 of the writing transistor T2. The active layer pattern T21 of the writing transistor T2 is electrically connected to the gate pattern T12 of the driving transistor T1 through a via hole and the source transfer pattern 1123 of the writing transistor T2. Specifically, the source region T21c of the active layer pattern T21 of the writing transistor T2 is electrically connected to the gate pattern T12 of the driving transistor T1 through the via hole and the source transfer pattern 1123 of the writing transistor T2.

The active layer pattern T31 of the sensing transistor T3 is electrically connected to a first sensing signal line 1153 through a via hole. Specifically, the drain region T31b of the active layer pattern T31 of the sensing transistor T3 is electrically connected to the first sensing signal line 1153 through the via hole. The active layer pattern T31 of the sensing transistor T3 is electrically connected to the anode transfer pattern 1152 through a via hole. Specifically, the source region T31c of the active layer pattern T31 of the sensing transistor T3 is electrically connected to the anode transfer pattern 1152 through the via hole.

For example, in the Z direction, there is an overlapping region CC between the active layer pattern T21 of the writing transistor T2 arranged in the first transistor distribution sub-layer 21 and the active layer pattern T31 of the sensing transistor T3 arranged in the third transistor distribution sub-layer 23. By setting the overlapping region CC, the area of the sub-pixel region A1 may be further reduced, which is beneficial to further improving the PPI of the array substrate 10.

The difference between the embodiments shown in FIG. 15 and the embodiments shown in FIG. 9A is as follows.

In the embodiments shown in FIG. 15, the driving transistor T1, the writing transistor T2, and the sensing transistor T3 are all oxide transistors.

The driving transistor T1 and the sensing transistor T3 in the embodiments shown in FIG. 15 are both dual-gate transistors. The bottom gate pattern T13 of the driving transistor T1 is arranged in the first gate film layer 111, and the bottom gate pattern T33 of the sensing transistor T3 is arranged in the fourth gate film layer 112.

In the embodiments shown in FIG. 15, the driving transistor T1 is arranged in the second transistor distribution sub-layer 22, and the writing transistor T2 is arranged in the first transistor distribution sub-layer 21.

In the embodiments shown in FIG. 15, the active layer pattern T11 of the driving transistor T1 is connected to the anode transfer pattern 1152 through a via hole and the first source transfer pattern 1121 of the driving transistor T1, and the active layer pattern T21 of the writing transistor T2 is electrically connected to the data signal line 1091 through a via hole and the second drain transfer pattern 1142 of the writing transistor T2.

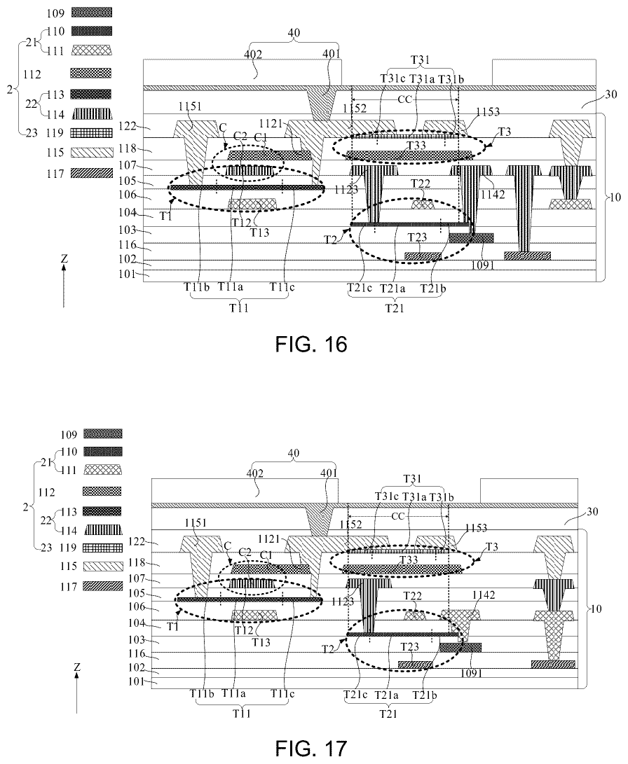

An array substrate 10 shown in FIG. 16 will be introduced below. In some embodiments, as shown in FIG. 16, FIG. 16 is a structural diagram of the array substrate 10, in accordance with some embodiments of the present disclosure. The array substrate 10 includes the base substrate 101, a first buffer layer 102, a light-shielding layer 117, a third buffer layer 116, a first source-drain metal layer 109, a first gate insulating layer 103, a first active film layer 110, a second gate insulating layer 104, a first gate film layer 111, a second buffer layer 106, a second active film layer 113, a third gate insulating layer 105, a second gate film layer 114, a fourth gate insulating layer 107, a fourth gate film layer 112, a fifth gate insulating layer 118, a third active film layer 119, a second source-drain metal layer 115 and a passivation layer 122 that are stacked in sequence.

It should be noted that, the embodiments are illustrated by taking an example where the light-shielding layer 117 is located on a side of the first source-drain metal layer 109 proximate to the base substrate 101 (that is, the light-shielding layer 117 is located between the first source-drain metal layer 109 and the base substrate 101). However, the positional relationship between the light-shielding layer 117 and the first source-drain metal layer 109 is not limited to this. For example, the positions of the light-shielding layer 117 and the first source-drain metal layer 109 can be interchangeable, and the light-shielding layer 117 is located on a side of the first source-drain metal layer 109 away from the base substrate 101 (that is, the first source-drain metal layer 109 is located between the light-shielding layer 117 and the base substrate 101).

Materials of the first active film layer 110, the second active film layer 113 and the third active film layer 119 may all be any one of indium gallium zinc oxide or low-temperature polycrystalline oxide. For example, the first active film layer 110, the second active film layer 113 and the third active film layer 119 are made of IGZO (indium gallium zinc oxide) or IGZTO (indium gallium zinc tin oxide).

For example, the first active film layer 110, the second active film layer 113 and the third active film layer 119 are all obtained by a PVD (physical vapor deposition) process.

The materials and manufacturing processes of the first buffer layer 102, the second buffer layer 106, the third buffer layer 116, the first gate insulating layer 103, the second gate insulating layer 104, the third gate insulating layer 105, the fourth gate insulating layer 107, the fifth gate insulating layer 118, the first gate film layer 111, the second gate film layer 114, the fourth gate film layer 112, the passivation layer 122 and the light-shielding layer 117 are basically the same as those in the above embodiments, which are not repeated here.

With continued reference to FIG. 16, the first transistor distribution sub-layer 21 includes the first active film layer 110 and the first gate film layer 111. The writing transistor T2 of the pixel driving circuit 20 is arranged in the first transistor distribution sub-layer 21. Since the first active film layer 110 may be made of any one of indium gallium zinc oxide or low-temperature polycrystalline oxide, the writing transistor T2 is an oxide transistor.

The second transistor distribution sub-layer 22 includes the second active film layer 113 and the second gate film layer 114. The driving transistor T1 of the pixel driving circuit 20 is arranged in the second transistor distribution sub-layer 22. Since the second active film layer 113 may be made of any one of indium gallium zinc oxide or low-temperature polycrystalline oxide, the driving transistor T1 is an oxide transistor.

The third transistor distribution sub-layer 23 includes the third active film layer 119, and the sensing transistor T3 of the pixel driving circuit 20 is arranged in the third transistor distribution sub-layer 23. Since the third active film layer 119 may be made of any one of indium gallium zinc oxide or low-temperature polycrystalline oxide, the sensing transistor T3 is an oxide transistor.

In the embodiments, the driving transistor T1 may be a dual-gate transistor, which includes the active layer pattern T11 of the driving transistor T1, the gate pattern T12 (top gate pattern) of the driving transistor T1, and a bottom gate pattern T13 of the driving transistor T1. The active layer pattern T11 of the driving transistor T1 is arranged in the second active film layer 113, the gate pattern T12 (top gate pattern) of the driving transistor T1 is arranged in the second gate film layer 114, and the bottom gate pattern T13 of the driving transistor T1 is arranged in the first gate film layer 111. The active layer pattern T11 of the driving transistor T1 includes a source region T11c of the driving transistor T1, a drain region T11b of the driving transistor T1, and a channel region T11a of the driving transistor T1 located between the source region T11c and the drain region T11b of the driving transistor T1.

In the embodiments, the writing transistor T2 may be a dual-gate transistor, which includes the active layer pattern T21 of the writing transistor T2, the gate pattern T22 (top gate pattern) of the writing transistor T2, and a bottom gate pattern T23 of the writing transistor T2. The active layer pattern T21 of the writing transistor T2 is arranged in the first active film layer 110, the gate pattern T22 (top gate pattern) of the writing transistor T2 is arranged in the first gate film layer 111, and the bottom gate pattern T23 of the writing transistor T2 is arranged in the light-shielding layer 117. The active layer pattern T21 of the writing transistor T2 includes a source region T21c of the writing transistor T2, a drain region T21b of the writing transistor T2, and a channel region T21a of the writing transistor T2 located between the source region T21c and the drain region T21b of the writing transistor T2.

In the embodiments, the sensing transistor T3 may be a bottom-gate transistor, which includes the active layer pattern T31 of the sensing transistor T3 and a bottom gate pattern T33 of the sensing transistor T3. The active layer pattern T31 of the sensing transistor T3 is arranged in the third active film layer 119, and the bottom gate pattern T33 of the sensing transistor T3 is arranged in the fourth gate film layer 112. The active layer pattern T31 of the sensing transistor T3 includes a source region T31c of the sensing transistor T3, a drain region T31b of the sensing transistor T3, and a channel region T31a of the sensing transistor T3 located between the source region T31c and the drain region T31b of the sensing transistor T3.

The first source-drain metal layer 109 includes data signal lines 1091.

The second gate film layer 114 includes a source transfer pattern 1123 of the writing transistor T2 and a second drain transfer pattern 1142 of the writing transistor T2. It should be noted that, in the embodiments, the second gate film layer 114 not only serves as the second transfer gate film layer, but also as the first transfer gate film layer.

The fourth gate film layer 112 includes a first source transfer pattern 1121 of the driving transistor T1. It should be noted that, in the embodiments, the fourth gate film layer 112 serves as the third transfer gate film layer.

Compared with the situation where source transfer patterns/drain transfer patterns of transistors are all arranged in the second source-drain metal layer 115′ in an embodiment shown in FIG. 5, in the embodiments, the fourth gate film layer 112 serves as the third transfer gate film layer, in which the first source transfer pattern 1121 of the driving transistor T1 is arranged, the second gate film layer 114 in the second transistor distribution sub-layer 22 serves as the second transfer gate film layer and the first transfer gate film layer, in which the source transfer pattern 1123 of the writing transistor T2 and the second drain transfer pattern 1142 of the writing transistor T2 are arranged. Thus, the wiring difficulty of other film layers (the second source-drain metal layer 115) in the array substrate 10 may be reduced, which is conducive to further improving the PPI (pixels per inch, pixel density) of the display panel 100.

The second source-drain metal layer 115 includes first voltage signal lines 1151, anode transfer patterns 1152, and first sensing signal lines 1153.

The active layer pattern T11 of the driving transistor T1 is connected to a first voltage signal line 1151 through a via hole. Specifically, the drain region T11b of the active layer pattern T11 of the driving transistor T1 is connected to the first voltage signal line 1151 through the via hole. The active layer pattern T11 of the driving transistor T1 is connected to an anode transfer pattern 1152 through a via hole and the first source transfer pattern 1121 of the driving transistor T1. Specifically, the source region T11c of the active layer pattern T11 of the driving transistor T1 is connected to the anode transfer pattern 1152 through the via hole and the first source transfer pattern 1121 of the driving transistor T1.

The active layer pattern T21 of the writing transistor T2 is electrically connected to a data signal line 1091 through a via hole and the second drain transfer pattern 1142 of the writing transistor T2. Specifically, the drain region T21b of the active layer pattern T21 of the writing transistor T2 is electrically connected to the data signal line 1091 through the via hole and the second drain transfer pattern 1142 of the writing transistor T2. The active layer pattern T21 of the writing transistor T2 is electrically connected to the gate pattern T12 of the driving transistor T1 through a via hole and the source transfer pattern 1123 of the writing transistor T2. Specifically, the source region T21c of the active layer pattern T21 of the writing transistor T2 is electrically connected to the gate pattern T12 of the driving transistor T1 through the via hole and the source transfer pattern 1123 of the writing transistor T2.

The active layer pattern T31 of the sensing transistor T3 is electrically connected to a first sensing signal line 1153. Specifically, the drain region T31b of the active layer pattern T31 of the sensing transistor T3 is electrically connected to the first sensing signal line 1153. The active layer pattern T31 of the sensing transistor T3 is electrically connected to the anode transfer pattern 1152. Specifically, the source region T31c of the active layer pattern T31 of the sensing transistor T3 is electrically connected to the anode transfer pattern 1152. The active layer pattern T31 of the sensing transistor T3 is directly electrically connected to the sensing signal line 1153 and the anode transfer pattern 1152 without the need for via holes, which may reduce the number of via holes on the second source-drain metal layer 115, and further reduce the number of same-direction via holes in the array substrate 10. Thus, the area of the sub-pixel region A1 may be further reduced, which is beneficial to improving the PPI of the array substrate 10.

For example, in the Z direction, there is an overlapping region CC between the active layer pattern T21 of the writing transistor T2 arranged in the first transistor distribution sub-layer 21 and the active layer pattern T31 of the sensing transistor T3 arranged in the third transistor distribution sub-layer 23. By setting the overlapping region CC, the area of the sub-pixel region A1 may be further reduced, which is beneficial to further improving the PPI of the array substrate 10.

The difference between the embodiments shown in FIG. 16 and the embodiments shown in FIG. 9A is as follows.

In the embodiments shown in FIG. 16, the driving transistor T1, the writing transistor T2, and the sensing transistor T3 are all oxide transistors.

In the embodiments shown in FIG. 16, the driving transistor T1 and the writing transistor T2 are both dual-gate transistors, and the sensing transistor T3 is a bottom-gate transistor. The bottom gate pattern T13 of the driving transistor T1 is arranged in the first gate film layer 111, and the bottom gate pattern T33 of the sensing transistor T3 is arranged in the fourth gate film layer 112.

In the embodiments shown in FIG. 16, the driving transistor T1 is arranged in the second transistor distribution sub-layer 22, and the writing transistor T2 is arranged in the first transistor distribution sub-layer 21.

In the embodiments shown in FIG. 16, the active layer pattern T11 of the driving transistor T1 is connected to the anode transfer pattern 1152 through a via hole and the first source transfer pattern 1121 of the driving transistor T1, and the active layer pattern T21 of the writing transistor T2 is electrically connected to the data signal line 1091 through a via hole and the second drain transfer pattern 1142 of the writing transistor T2.

An array substrate 10 shown in FIG. 17 will be introduced below. In some embodiments, as shown in FIG. 17, FIG. 17 is a structural diagram of the array substrate 10, in accordance with some embodiments of the present disclosure. The array substrate 10 includes the base substrate 101, a first buffer layer 102, a light-shielding layer 117, a third buffer layer 116, a first source-drain metal layer 109, a first gate insulating layer 103, a first active film layer 110, a second gate insulating layer 104, a first gate film layer 111, a second buffer layer 106, a second active film layer 113, a third gate insulating layer 105, a second gate film layer 114, a fourth gate insulating layer 107, a fourth gate film layer 112, a fifth gate insulating layer 118, a third active film layer 119, a second source-drain metal layer 115 and a passivation layer 122 that are stacked in sequence.

It should be noted that, the embodiments are illustrated by taking an example where the light-shielding layer 117 is located on a side of the first source-drain metal layer 109 proximate to the base substrate 101 (that is, the light-shielding layer 117 is located between the first source-drain metal layer 109 and the base substrate 101). However, the positional relationship between the light-shielding layer 117 and the first source-drain metal layer 109 is not limited to this. For example, the positions of the light-shielding layer 117 and the first source-drain metal layer 109 can be interchangeable, and the light-shielding layer 117 is located on a side of the first source-drain metal layer 109 away from the base substrate 101 (that is, the first source-drain metal layer 109 is located between the light-shielding layer 117 and the base substrate 101).

Materials of the first active film layer 110, the second active film layer 113 and the third active film layer 119 may all be any one of indium gallium zinc oxide or low-temperature polycrystalline oxide. For example, the first active film layer 110, the second active film layer 113 and the third active film layer 119 are made of IGZO (indium gallium zinc oxide) or IGZTO (indium gallium zinc tin oxide).

For example, the first active film layer 110, the second active film layer 113 and the third active film layer 119 are all obtained by a PVD (physical vapor deposition) process.

The materials and manufacturing processes of the first buffer layer 102, the second buffer layer 106, the third buffer layer 116, the first gate insulating layer 103, the second gate insulating layer 104, the third gate insulating layer 105, the fourth gate insulating layer 107, the fifth gate insulating layer 118, the first gate film layer 111, the second gate film layer 114, the fourth gate film layer 112, the passivation layer 122 and the light-shielding layer 117 are basically the same as those in the above embodiments, which are not repeated here.

With continued reference to FIG. 17, the first transistor distribution sub-layer 21 includes the first active film layer 110 and the first gate film layer 111. The writing transistor T2 of the pixel driving circuit 20 is arranged in the first transistor distribution sub-layer 21. Since the first active film layer 110 may be made of any one of indium gallium zinc oxide or low-temperature polycrystalline oxide, the writing transistor T2 is an oxide transistor.

The second transistor distribution sub-layer 22 includes the second active film layer 113 and the second gate film layer 114. The driving transistor T1 of the pixel driving circuit 20 is arranged in the second transistor distribution sub-layer 22. Since the second active film layer 113 may be made of any one of indium gallium zinc oxide or low-temperature polycrystalline oxide, the driving transistor T1 is an oxide transistor.

The third transistor distribution sub-layer 23 includes the third active film layer 119, and the sensing transistor T3 of the pixel driving circuit 20 is arranged in the third transistor distribution sub-layer 23. Since the third active film layer 119 may be made of any one of indium gallium zinc oxide or low-temperature polycrystalline oxide, the sensing transistor T3 is an oxide transistor.

In the embodiments, the driving transistor T1 may be a dual-gate transistor, which includes the active layer pattern T11 of the driving transistor T1, the gate pattern T12 (top gate pattern) of the driving transistor T1, and a bottom gate pattern T13 of the driving transistor T1. The active layer pattern T11 of the driving transistor T1 is arranged in the second active film layer 113, the gate pattern T12 (top gate pattern) of the driving transistor T1 is arranged in the second gate film layer 114, and the bottom gate pattern T13 of the driving transistor T1 is arranged in the first gate film layer 111. The active layer pattern T11 of the driving transistor T1 includes a source region T11c of the driving transistor T1, a drain region T11b of the driving transistor T1, and a channel region T11a of the driving transistor T1 located between the source region T11c and the drain region T11b of the driving transistor T1.

In the embodiments, the writing transistor T2 may be a dual-gate transistor, which includes the active layer pattern T21 of the writing transistor T2, the gate pattern T22 (top gate pattern) of the writing transistor T2, and a bottom gate pattern T23 of the writing transistor T2. The active layer pattern T21 of the writing transistor T2 is arranged in the first active film layer 110, the gate pattern T22 (top gate pattern) of the writing transistor T2 is arranged in the first gate film layer 111, and the bottom gate pattern T23 of the writing transistor T2 is arranged in the light-shielding layer 117. The active layer pattern T21 of the writing transistor T2 includes a source region T21c of the writing transistor T2, a drain region T21b of the writing transistor T2, and a channel region T21a of the writing transistor T2 located between the source region T21c and the drain region T21b of the writing transistor T2.

In the embodiments, the sensing transistor T3 may be a bottom-gate transistor, which includes the active layer pattern T31 of the sensing transistor T3 and a bottom gate pattern T33 of the sensing transistor T3. The active layer pattern T31 of the sensing transistor T3 is arranged in the third active film layer 119, and the bottom gate pattern T33 of the sensing transistor T3 is arranged in the fourth gate film layer 112. The active layer pattern T31 of the sensing transistor T3 includes a source region T31c of the sensing transistor T3, a drain region T31b of the sensing transistor T3, and a channel region T31a of the sensing transistor T3 located between the source region T31c and the drain region T31b of the sensing transistor T3.

The first source-drain metal layer 109 includes data signal lines 1091.

The first gate film layer 111 includes a second drain transfer pattern 1142 of the writing transistor T2. It should be noted that, in the embodiments, the first gate film layer 111 serves as the first transfer gate film layer.

The second gate film layer 114 includes a source transfer pattern 1123 of the writing transistor T2. It should be noted that, in the embodiments, the second gate film layer 114 serves as the second transfer gate film layer.

The fourth gate film layer 112 includes a first source transfer pattern 1121 of the driving transistor T1. It should be noted that, in the embodiments, the fourth gate film layer 112 serves as the third transfer gate film layer.

Compared with the situation where source transfer patterns/drain transfer patterns of transistors are all arranged in the second source-drain metal layer 115′ in an embodiment shown in FIG. 5, in the embodiments, the fourth gate film layer 112 serves as the third transfer gate film layer, in which the first source transfer pattern 1121 of the driving transistor T1 is arranged, the second gate film layer 114 in the second transistor distribution sub-layer 22 serves as the second transfer gate film layer, in which the source transfer pattern 1123 of the writing transistor T2 is arranged, and the first gate film layer 111 in the first transistor distribution sub-layer 21 serves as the first transfer gate film layer, in which the second drain transfer pattern 1142 of the writing transistor T2 is arranged. Thus, the wiring difficulty of other film layers (the second source-drain metal layer 115) in the array substrate 10 may be reduced, which is conducive to further improving the PPI (pixels per inch, pixel density) of the display panel 100.

The second source-drain metal layer 115 includes first voltage signal lines 1151, anode transfer patterns 1152, and first sensing signal lines 1153.

The active layer pattern T11 of the driving transistor T1 is connected to a first voltage signal line 1151 through a via hole. Specifically, the drain region T11b of the active layer pattern T11 of the driving transistor T1 is connected to the first voltage signal line 1151 through the via hole. The active layer pattern T11 of the driving transistor T1 is connected to an anode transfer pattern 1152 through a via hole and the first source transfer pattern 1121 of the driving transistor T1. Specifically, the source region T11c of the active layer pattern T11 of the driving transistor T1 is connected to the anode transfer pattern 1152 through the via hole and the first source transfer pattern 1121 of the driving transistor T1.

The active layer pattern T21 of the writing transistor T2 is electrically connected to a data signal line 1091 through a via hole and the second drain transfer pattern 1142 of the writing transistor T2. Specifically, the drain region T21b of the active layer pattern T21 of the writing transistor T2 is electrically connected to the data signal line 1091 through the via hole and the second drain transfer pattern 1142 of the writing transistor T2. The active layer pattern T21 of the writing transistor T2 is electrically connected to the gate pattern T12 of the driving transistor T1 through a via hole and the source transfer pattern 1123 of the writing transistor T2. Specifically, the source region T21c of the active layer pattern T21 of the writing transistor T2 is electrically connected to the gate pattern T12 of the driving transistor T1 through the via hole and the source transfer pattern 1123 of the writing transistor T2.

The active layer pattern T31 of the sensing transistor T3 is electrically connected to a first sensing signal line 1153. Specifically, the drain region T31b of the active layer pattern T31 of the sensing transistor T3 is electrically connected to the first sensing signal line 1153. The active layer pattern T31 of the sensing transistor T3 is electrically connected to the anode transfer pattern 1152. Specifically, the source region T31c of the active layer pattern T31 of the sensing transistor T3 is electrically connected to the anode transfer pattern 1152. The active layer pattern T31 of the sensing transistor T3 is directly electrically connected to the sensing signal line 1153 and the anode transfer pattern 1152 without the need for via holes, which may reduce the number of via holes on the second source-drain metal layer 115, and further reduce the number of same-direction via holes in the array substrate 10. Thus, the area of the sub-pixel region A1 may be further reduced, which is beneficial to improving the PPI of the array substrate 10.

For example, in the Z direction, there is an overlapping region CC between the active layer pattern T21 of the writing transistor T2 arranged in the first transistor distribution sub-layer 21 and the active layer pattern T31 of the sensing transistor T3 arranged in the third transistor distribution sub-layer 23. That is, in a sub-pixel region A1, the writing transistor T2 and the sensing transistor T3 have the overlapping region CC. By setting the overlapping region CC, the area of the sub-pixel region A1 may be further reduced, which is beneficial to further improving the PPI of the array substrate 10.

The difference between the embodiments shown in FIG. 17 and the embodiments shown in FIG. 9A is as follows.

In the embodiments shown in FIG. 17, the driving transistor T1, the writing transistor T2, and the sensing transistor T3 are all oxide transistors.

In the embodiments shown in FIG. 17, the driving transistor T1 and the writing transistor T2 are both dual-gate transistors, and the sensing transistor T3 is a bottom-gate transistor. The bottom gate pattern T13 of the driving transistor T1 is arranged in the first gate film layer 111, and the bottom gate pattern T33 of the sensing transistor T3 is arranged in the fourth gate film layer 112.

In the embodiments shown in FIG. 17, the driving transistor T1 is arranged in the second transistor distribution sub-layer 22, and the writing transistor T2 is arranged in the first transistor distribution sub-layer 21.

In the embodiments shown in FIG. 17, the active layer pattern T11 of the driving transistor T1 is connected to the anode transfer pattern 1152 through a via hole and the first source transfer pattern 1121 of the driving transistor T1, and the active layer pattern T21 of the writing transistor T2 is electrically connected to the data signal line 1091 through a via hole and the second drain transfer pattern 1142 of the writing transistor T2.

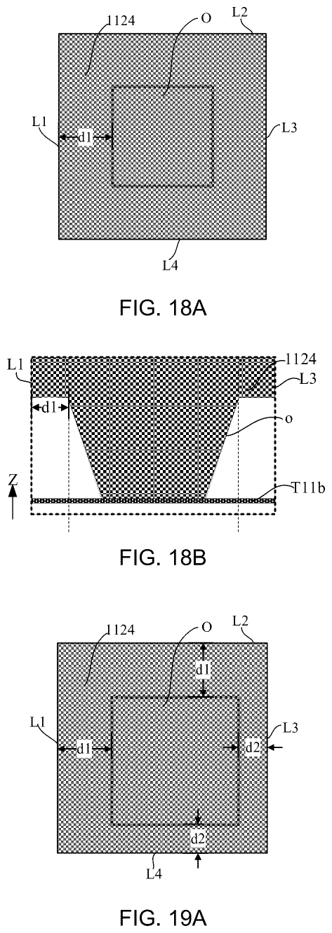

In some embodiments, as shown in FIGS. 18A to 20B, FIGS. 18A to 20B are structural diagrams of the drain transfer pattern 1124 of the driving transistor T1, in accordance with some embodiments of the present disclosure. The symbol “O” is used to represent a via hole. It should be noted that, in order to clearly show the position and structure of the via hole in FIGS. 18A, 19A and 20A, the drain transfer pattern 1124 of the driving transistor T1 is transparent to present the via hole located on a side of the drain transfer pattern 1124 of the driving transistor T1 proximate to the base substrate 101.

The drain region T11b of the active layer pattern T11 of the driving transistor T1 is connected to the drain transfer pattern 1124 of the driving transistor T1 through the via hole.

For example, the drain transfer pattern 1124 of the driving transistor T1 may be in a shape of a quadrilateral, an octagon, or any other shape with sides and corners. FIGS. 18A to 20B are only illustrated by taking an example where the drain transfer pattern 1124 of the driving transistor T1 is in the shape of the quadrilateral.

In the case where the drain transfer pattern 1124 of the driving transistor T1 is in the shape of the quadrilateral, the drain transfer pattern 1124 of the driving transistor T1 includes four sides, which are a first side L1, a second side L2, a third side L3 and a fourth side L4. The first side L1 and the third side L3 are arranged oppositely, and the second side L2 and the fourth side L4 are arranged oppositely. As shown in FIGS. 18A and 18B, a distance between each of the four sides of the drain transfer pattern 1124 of the driving transistor T1 and a corresponding side of the via hole may be the same, which may be d1. In this way, an area of an orthographic projection of the drain transfer pattern 1124 of the driving transistor T1 on the base substrate 101 is relatively large, which is beneficial to improving the connection stability between the drain transfer pattern 1124 of the driving transistor T1 and both the first voltage signal line 1151 and the drain region T11b of the active layer pattern T11 of the driving transistor T1.

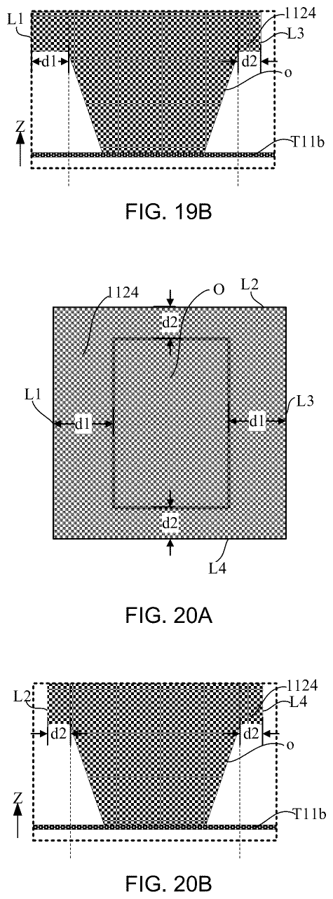

Alternatively, as shown in FIGS. 19A, 19B, 20A, and 20B, distances between the four sides of the drain transfer pattern 1124 of the driving transistor T1 and respective sides of the via hole may also be different.

For example, as shown in FIGS. 19A and 19B, a distance between the first side L1 of the drain transfer pattern 1124 of the driving transistor T1 and a corresponding side of the via hole is equal to a distance between the second side L2 of the drain transfer pattern 1124 of the driving transistor T1 and a corresponding side of the via hole, and both are d1; a distance between the third side L3 of the drain transfer pattern 1124 of the driving transistor T1 and a corresponding side of the via hole is equal to a distance between the fourth side L4 of the drain transfer pattern 1124 of the driving transistor T1 and a corresponding side of the via hole, and both are d2. d1 and d2 are different, and d1 is greater than d2.

For another example, as shown in FIGS. 20A and 20B, a distance between the first side L1 of the drain transfer pattern 1124 of the driving transistor T1 and a corresponding side of the via hole is equal to a distance between the third side L3 of the drain transfer pattern 1124 of the driving transistor T1 and a corresponding side of the via hole, and both are d1; a distance between the second side L2 of the drain transfer pattern 1124 of the driving transistor T1 and a corresponding side of the via hole is equal to a distance between the fourth side L4 of the drain transfer pattern 1124 of the driving transistor T1 and a corresponding side of the via hole, and both are d2. d1 and d2 are different, and d1 is greater than d2. In this way, it may be ensured that the spacing between the drain transfer pattern 1124 of the driving transistor T1 and other transfer patterns, signal lines or the first electrode plate C1 of the capacitor C in the fourth gate film layer 112, which avoids the short circuit caused by the small spacing between the drain transfer pattern 1124 of the driving transistor T1 and other transfer patterns, signal lines or the first electrode plate C1 of the capacitor C in the fourth gate film layer 112, and avoids affecting the normal display of the array substrate 10.

It should be noted that, the above-mentioned “side of the via hole” refers to the maximum side of the orthographic projection of the via hole on the drain transfer pattern 1124 of the driving transistor T1.

FIGS. 18A to 20B illustrate the relationship between the drain transfer pattern 1124 of the driving transistor T1 and the via hole by taking an example of the drain transfer pattern 1124 of the driving transistor T1. Other transfer patterns (such as the source transfer pattern 1123 of the writing transistor T2 and the first source transfer pattern 1121 of the driving transistor T1) in various embodiments of the present disclosure may also be arranged as described above. Although some embodiments of the present disclosure are described herein in combination with FIGS. 6 to 17, the above description is exemplary and not exhaustive; and therefore, the present disclosure is not limited to the disclosed embodiments. Many modifications and variations will be apparent to those of ordinary skill in the art without departing from the scope of the above embodiments.

The foregoing descriptions are merely specific implementations of the present disclosure, but the protection scope of the present application is not limited thereto. Variations or replacements that any person skilled in the art could readily conceive of within the technical scope disclosed in the present disclosure shall be included in the protection scope of the present disclosure. Therefore, the protection scope of the present disclosure should be subject to the protection scope of the claims.

1. An array substrate, comprising: a plurality of pixel driving circuits arranged in rows and columns, wherein each of the plurality of pixel driving circuits includes a plurality of transistors, and the plurality of transistors includes at least a writing transistor, wherein
the array substrate comprises:
a base substrate;
a first source-drain metal layer disposed on a side of the base substrate, the first source-drain metal layer including data signal lines;
a transistor distribution layer disposed on a side of the first source-drain metal layer away from the base substrate, wherein the transistor distribution layer is provided with an active layer pattern of the writing transistor, and the active layer pattern of the writing transistor is electrically connected to a data signal line of the data signal lines; and
a second source-drain metal layer disposed on a side of the transistor distribution layer away from the base substrate, the second source-drain metal layer including anode transfer patterns.

2. The array substrate according to claim 1, wherein the transistor distribution layer includes at least two transistor distribution sub-layers that are stacked, and each of the at least two transistor distribution sub-layers includes an active film layer and a gate film layer that are stacked; the active film layer includes an active layer pattern of a transistor of the plurality of transistors, and the gate film layer includes a gate pattern of the transistor; and the writing transistor is located in one of the at least two transistor distribution sub-layers;
the active layer pattern of the writing transistor is electrically connected to the data signal line through a drain transfer pattern of the writing transistor, and the drain transfer pattern of the writing transistor is located in a first transfer gate film layer; and
the first transfer gate film layer is located in the at least two transistor distribution sub-layers and/or between two adjacent transistor distribution sub-layers.

3. The array substrate according to claim 2, wherein the active layer pattern of the writing transistor is connected to a source transfer pattern of the writing transistor, wherein
the source transfer pattern of the writing transistor is located in a second transfer gate film layer; and
the second transfer gate film layer is located in the at least two distribution sub-layers and/or between two adjacent transistor distribution sub-layers.

4. The array substrate according to claim 2, wherein the pixel driving circuit further includes a driving transistor and a sensing transistor, an active layer pattern of the driving transistor is electrically connected to an anode transfer pattern of the anode transfer patterns, and an active layer pattern of the sensing transistor is electrically connected to the anode transfer pattern; and
the active layer pattern of the driving transistor is connected to the anode transfer pattern through a source transfer pattern of the driving transistor, the source transfer pattern of the driving transistor is located in a third transfer gate film layer, and the third transfer gate film layer is located in the at least two transistor distribution sub-layers and/or between two adjacent transistor distribution sub-layers.

5. The array substrate according to claim 2, wherein the transistor distribution layer includes a first transistor distribution sub-layer and a second transistor distribution sub-layer that are stacked, and the first transistor distribution sub-layer is closer to the base substrate than the second transistor distribution sub-layer;
the transistor distribution layer further includes a fourth gate film layer located between the first transistor distribution sub-layer and the second transistor distribution sub-layer;
the writing transistor is located in the first transistor distribution sub-layer; and
the drain transfer pattern and a source transfer pattern of the writing transistor are located in the fourth gate film layer, and the source transfer pattern of the writing transistor is connected to the active layer pattern of the writing transistor.

6. The array substrate according to claim 5, wherein the pixel driving circuit further includes a driving transistor, and the driving transistor is located in the first transistor distribution sub-layer; and
a source transfer pattern of the driving transistor is located in the fourth gate film layer, and the source transfer pattern of the driving transistor is connected to an anode transfer pattern of the anode transfer patterns.

7. The array substrate according to claim 5, wherein the pixel driving circuit further includes a sensing transistor, and the sensing transistor is located in the second transistor distribution sub-layer; and
the second source-drain metal layer further includes first sensing signal lines, and an active layer pattern of the sensing transistor is connected to a first sensing signal line of the first sensing signal lines.

8. The array substrate according to claim 5, wherein an active film layer of the first transistor distribution sub-layer is a polysilicon active film layer, and an active film layer of the second transistor distribution sub-layer is an oxide active film layer.

9. The array substrate according to claim 2, wherein the transistor distribution layer includes a first transistor distribution sub-layer, a second transistor distribution sub-layer, and a third transistor distribution sub-layer that are stacked in sequence, and the first transistor distribution sub-layer is closer to the base substrate than the second transistor distribution sub-layer;
the transistor distribution layer further includes a fourth gate film layer located between the first transistor distribution sub-layer and the second transistor distribution sub-layer;
the writing transistor is located in the second transistor distribution sub-layer;
the drain transfer pattern of the writing transistor includes a first drain transfer pattern and a second drain transfer pattern;
the first drain transfer pattern of the writing transistor is located in the fourth gate film layer, and the first drain transfer pattern of the writing transistor is connected to the second drain transfer pattern of the writing transistor and is connected to the data signal line;
the second drain transfer pattern of the writing transistor is located in a gate film layer of the second transistor distribution sub-layer, and the second drain transfer pattern of the writing transistor is connected to the active layer pattern of the writing transistor; and
a source transfer pattern of the writing transistor is located in the gate film layer of the second transistor distribution sub-layer, and the source transfer pattern of the writing transistor is connected to the active layer pattern of the writing transistor.

10. The array substrate according to claim 9, wherein the pixel driving circuit further includes a driving transistor and a sensing transistor; the driving transistor is located in the first transistor distribution sub-layer, and the sensing transistor is located in the third transistor distribution sub-layer.

11. The array substrate according to claim 10, wherein the third transistor distribution sub-layer includes a third active film layer and a third gate film layer, and the third active film layer is closer to the base substrate than the third gate film layer;
a source transfer pattern of the driving transistor includes a first source transfer pattern and a second source transfer pattern;
the first source transfer pattern of the driving transistor is located in the fourth gate film layer, and the second source transfer pattern of the driving transistor is located in the gate film layer of the second transistor distribution sub-layer; and
the first source transfer pattern of the driving transistor is connected to an active layer pattern of the driving transistor, and the second source transfer pattern of the driving transistor is connected to the first source transfer pattern of the driving transistor and is connected to an anode transfer pattern of the anode transfer patterns.

12. The array substrate according to claim 10, wherein the third transistor distribution sub-layer includes a third active film layer and a third gate film layer, and the third active film layer is farther away from the base substrate than the third gate film layer;
the second transistor distribution sub-layer includes a second active film layer and a second gate film layer, and the second active film layer is closer to the base substrate than the second gate film layer;
the third gate film layer and the second gate film layer are a same film layer; and
a source transfer pattern of the driving transistor is located in the fourth gate film layer, and the source transfer pattern of the driving transistor is connected to an anode transfer pattern of the anode transfer patterns.

13. The array substrate according to claim 10, wherein the second source-drain metal layer further includes first voltage signal lines;
an active layer pattern of the driving transistor is connected to a first voltage signal line of the first voltage signal lines through a drain transfer pattern of the driving transistor; and
the drain transfer pattern of the driving transistor is located in the fourth gate film layer.

14. The array substrate according to claim 10, wherein the array substrate further comprises a third source-drain metal layer located on a side of the second source-drain metal layer away from the base substrate; the second source-drain metal layer further includes sensing patterns, and an active layer pattern of the sensing transistor is connected to a sensing pattern of the sensing patterns; and the third source-drain metal layer includes first sensing signal lines, and a first sensing signal line is connected to the sensing pattern.

15. (canceled)

16. The array substrate according to claim 2, wherein the transistor distribution layer includes a first transistor distribution sub-layer, a second transistor distribution sub-layer, and a third transistor distribution sub-layer that are stacked, and the first transistor distribution sub-layer is closer to the base substrate than the second transistor distribution sub-layer;
the writing transistor is located in the first transistor distribution sub-layer;
the drain transfer pattern of the writing transistor is located in a gate film layer of the second transistor distribution sub-layer, or the drain transfer pattern of the writing transistor is located in a gate film layer of the first transistor distribution sub-layer; and
a source transfer pattern of the writing transistor is located in the gate film layer of the second transistor distribution sub-layer, and the source transfer pattern of the writing transistor is connected to the active layer pattern of the writing transistor.

17. The array substrate according to claim 16, wherein the pixel driving circuit further includes a driving transistor and a sensing transistor; the driving transistor is located in the second transistor distribution sub-layer, and the sensing transistor is located in the third transistor distribution sub-layer; and
the second source-drain metal layer further includes first sensing signal lines, and an active layer pattern of the sensing transistor is connected to a first sensing signal line of the first sensing signal lines.

18. The array substrate according to claim 17, wherein the third transistor distribution sub-layer includes a third active film layer and a third gate film layer, and the third active film layer is closer to the base substrate than the third gate film layer; or
the third transistor distribution sub-layer includes a third active film layer and a third gate film layer, and the third active film layer is farther away from the base substrate than the third gate film layer; the transistor distribution layer further includes a fourth gate film layer located between the second transistor distribution sub-layer and the third active film layer, and the fourth gate film layer and the third gate film layer are a same film layer; and
a source transfer pattern of the driving transistor is located in the fourth gate film layer, and the source transfer pattern of the driving transistor is connected to an anode transfer pattern of the anode transfer patterns.

19. (canceled)

20. The array substrate according to claim 2, wherein the array substrate further comprises a light-shielding layer;
the light-shielding layer is located on a side of the first source-drain metal layer close to the base substrate, or the light-shielding layer is located on a side of the first source-drain metal layer away from the base substrate;
at least one transistor disposed in a transistor distribution sub-layer in the transistor distribution layer closest to the base substrate is a dual-gate transistor;
a gate film layer of the transistor distribution sub-layer closest to the base substrate is located on a side of an active film layer of the transistor distribution sub-layer away from the base substrate, and the gate film layer includes a top gate pattern of the dual-gate transistor; and
the light-shielding layer includes a bottom gate pattern of the dual-gate transistor.

21. A display panel, comprising the array substrate according to claim 1; and
an anode layer disposed on the array substrate, wherein the anode layer is connected to the anode transfer patterns.

22. A display apparatus, comprising the display panel according to claim 21.
